(19) United States
(12) Patent Application Publication
(10) Pub. No.: US 2019/0378850 A1
(43) Pub. Date: Dec. 12, 2019

(54) VERTICAL MEMORY DEVICES

(71) Applicant: Samsung Electronics Co., Ltd., Suwon-si (KR)

(72) Inventors: Seon-Ho YOON, Suwon-si (KR); Seok-Cheon Baek, Hwaseong-si (KR); Ji-Sung Cheon, Ansan-si (KR); Eun-Taek Jung, Seongnam-si (KR)

(21) Appl. No.: 16/239,809

(22) Filed: Jan. 4, 2019

(30) Foreign Application Priority Data
Jun. 8, 2018 (KR) 10-2018-0066115

(51) Int. Cl. H01L 27/11556; H01L 27/11582; H01L 27/11526; H01L 27/11573; H01L 21/311; H01L 21/3213

(52) U.S. Cl. CPC H01L 27/11556; H01L 27/11582; H01L 27/11526; H01L 27/11519; H01L 21/31144; H01L 21/32139; H01L 27/11573

(57) ABSTRACT

A vertical memory device includes: a gate electrode structure including a ground selection line (GSL), a word line and a string selection line (SSL) sequentially stacked on a substrate in a first direction substantially perpendicular to an upper surface of the substrate; and a channel extending through the gate electrode structure in the first direction, wherein the GSL has a doped polysilicon pattern and a first metal pattern including a metal or a metal silicide, and the doped polysilicon pattern and the first metal pattern are stacked in the first direction, and wherein each of the word line and the SSL has a second metal pattern including a metal.

### CROSS-REFERENCE TO RELATED APPLICATION

This application claims priority under 35 U.S.C. § 119 to Korean Patent Application No. 10-2018-0066115, filed on Jun. 8, 2018 in the Korean Intellectual Property Office (KIPO), the disclosure of which is incorporated by reference herein in its entirety.

### 1. TECHNICAL FIELD

Exemplary embodiments of the inventive concept relate to a vertical memory device.

### 2. DESCRIPTION OF THE RELATED ART

Vertical NAND (VNAND) flash memory technology involves stacking memory cells vertically in a three-dimensional structure, for example. In a method of manufacturing a VNAND flash memory device having a cell-over-peri (COP) structure, when channel holes are formed to expose a base layer which is formed of polysilicon, the channel holes may have uneven depths, and thus, current applied to the channels may not be constant. For example, a selective epitaxial growth process may be performed to form an epitaxial layer under each channel; however, since the channel holes have uneven depths, height distribution between the epitaxial layers in the channel holes may be uneven. Thus, the electrical characteristics of memory cells including the channels may not be uniform.

### SUMMARY

According to an exemplary embodiment of the inventive concept, there is provided a vertical memory device including: a gate electrode structure including a ground selection line (GSL), a word line and a string selection line (SSL) sequentially stacked on a substrate in a first direction substantially perpendicular to an upper surface of the substrate; and a channel extending through the gate electrode structure in the first direction, wherein the GSL has a doped polysilicon pattern and a first metal pattern including a metal or a metal silicide, and the doped polysilicon pattern and the first metal pattern are stacked in the first direction, and wherein each of the word line and the SSL has a second metal pattern including a metal.

According to an exemplary embodiment of the inventive concept, there is provided a vertical memory device including: a gate electrode structure including a GSL, a word line and an SSL sequentially stacked on a substrate in a first direction substantially perpendicular to an upper surface of the substrate; and a channel extending through the gate electrode structure in the first direction, wherein the GSL has a doped polysilicon pattern and a first metal pattern including a metal or a metal silicide, and the doped polysilicon pattern and the first metal pattern are arranged in a second direction substantially parallel to the upper surface of the substrate, and wherein each of the word line and the SSL has a second metal pattern including a metal.

According to an exemplary embodiment of the inventive concept, there is provided a vertical memory device including: a gate electrode structure including a plurality of gate electrodes sequentially stacked in a vertical direction with respect to an upper surface of a substrate; and a channel structure extending through the gate electrode structure in the vertical direction, wherein a first gate electrode of the plurality of gate electrodes has a doped polysilicon pattern and a first metal pattern, and wherein each of second gate electrodes of the plurality of gate electrodes has a second metal pattern.

### BRIEF DESCRIPTION OF THE :DRAWINGS

FIGS. 1, 2, 3, 4, 5, 6, 7, 8, 9, 10, 11, 12, 13, 14, 15, 16, 17, 18, 19, 20 and 21 are plan views and cross-sectional views illustrating a method of manufacturing a vertical memory device in accordance with exemplary embodiments of the inventive concept.

FIGS. 22, 23 and 24 are cross-sectional views illustrating a vertical memory device in accordance with exemplary embodiments of the inventive concept.

FIGS. 25 and 26 are cross-sectional views taken along lines A-A′ of FIG. 1 illustrating a method of manufacturing a vertical memory device in accordance with exemplary embodiments of the inventive concept.

FIGS. 27, 26 and 29 are cross-sectional views illustrating a vertical memory device in accordance with exemplary embodiments of the inventive concept.

FIGS. 30 and 31 are cross-sectional views illustrating a vertical memory device in accordance with exemplary embodiments of the inventive concept.

FIG. 32 is a cross-sectional view illustrating a vertical memory device in accordance with exemplary embodiments of the inventive concept.

FIGS. 33, 34, 35 and 36 arc cross-sectional views illustrating a method of manufacturing a vertical memory device in accordance with exemplary embodiments of the inventive concept.

FIGS. 37, 38, 39, 40 and 41 are cross-sectional views illustrating a method of manufacturing a vertical memory device in accordance with exemplary embodiments of the inventive concept.

FIGS. 42, 43, 44, 45 and 46 are cross-sectional views illustrating a method of manufacturing a vertical memory device in accordance with exemplary embodiments of the inventive concept.

FIG. 47 is a cross-sectional view illustrating a vertical memory device in accordance with exemplary embodiments of the inventive concept.

### DETAILED DESCRIPTION OF THE EMBODIMENTS

A vertical memory device and a method of manufacturing the same in accordance with exemplary embodiments of the inventive concept will be described more fully hereinafter with reference to the accompanying drawings.

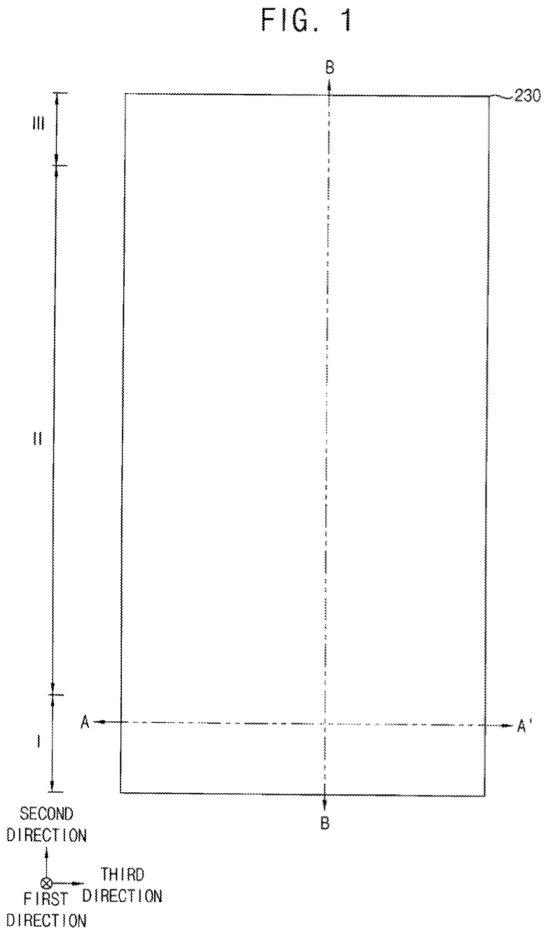

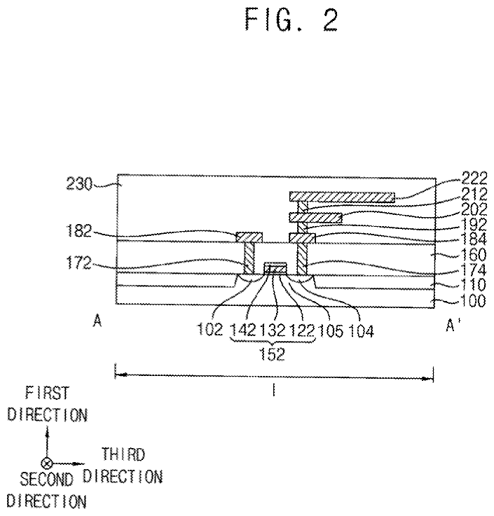

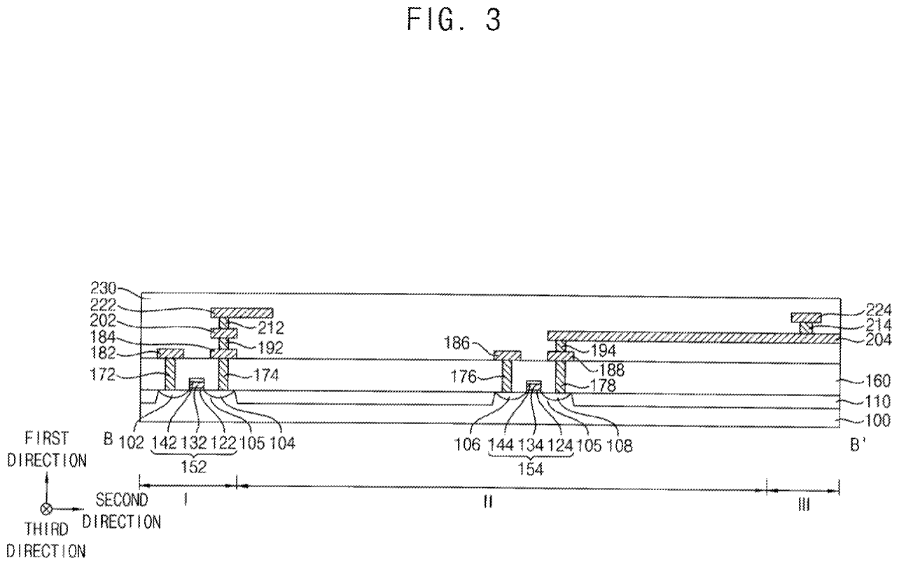

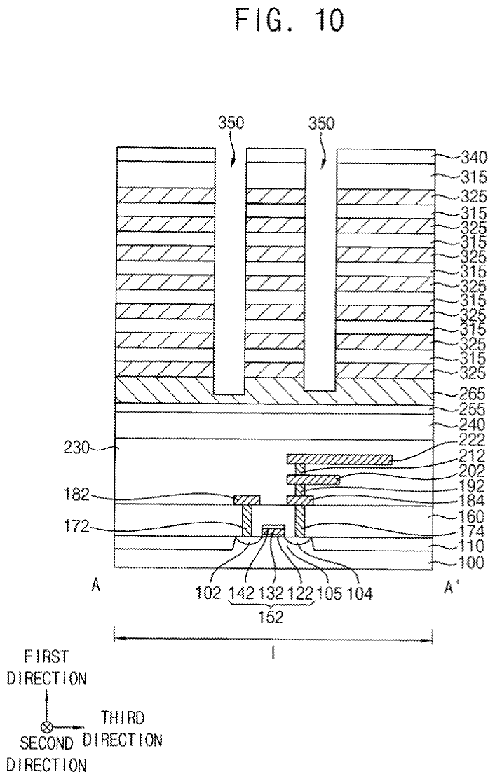

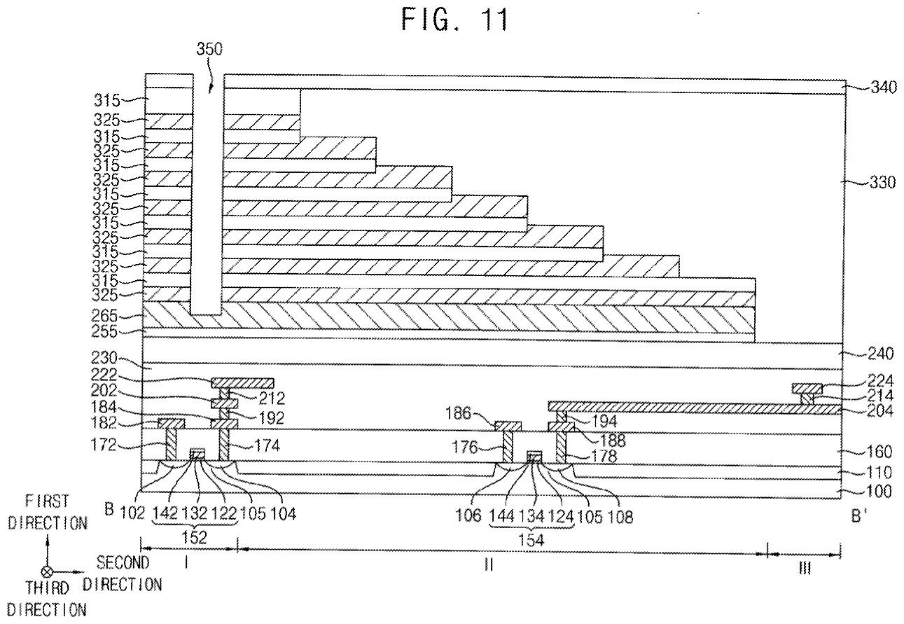

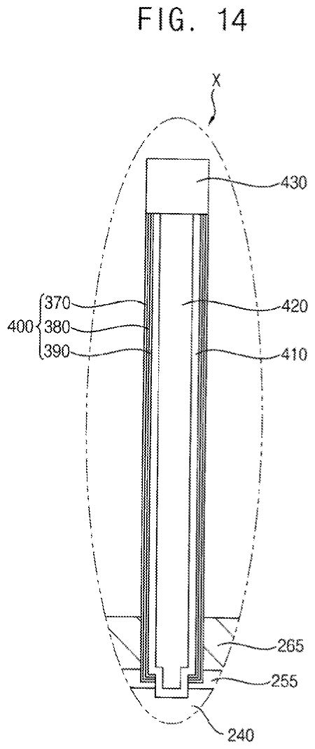

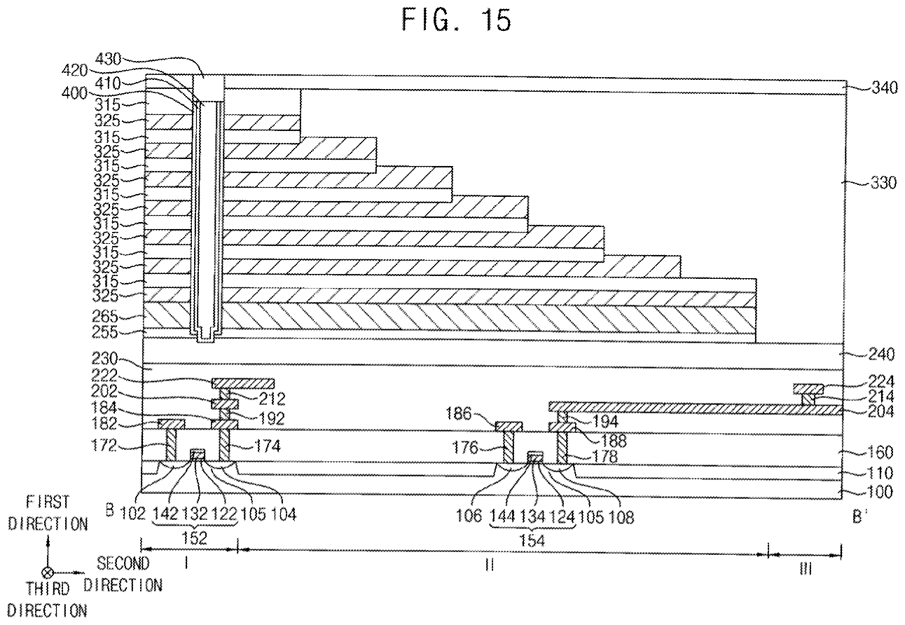

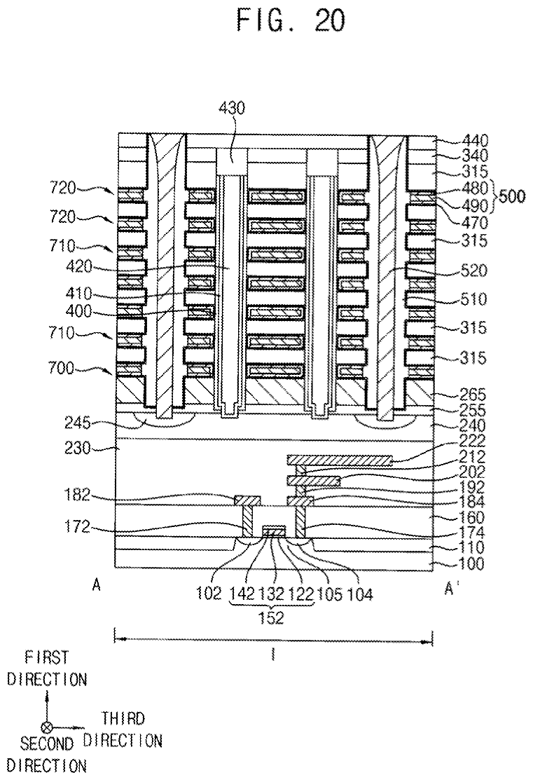

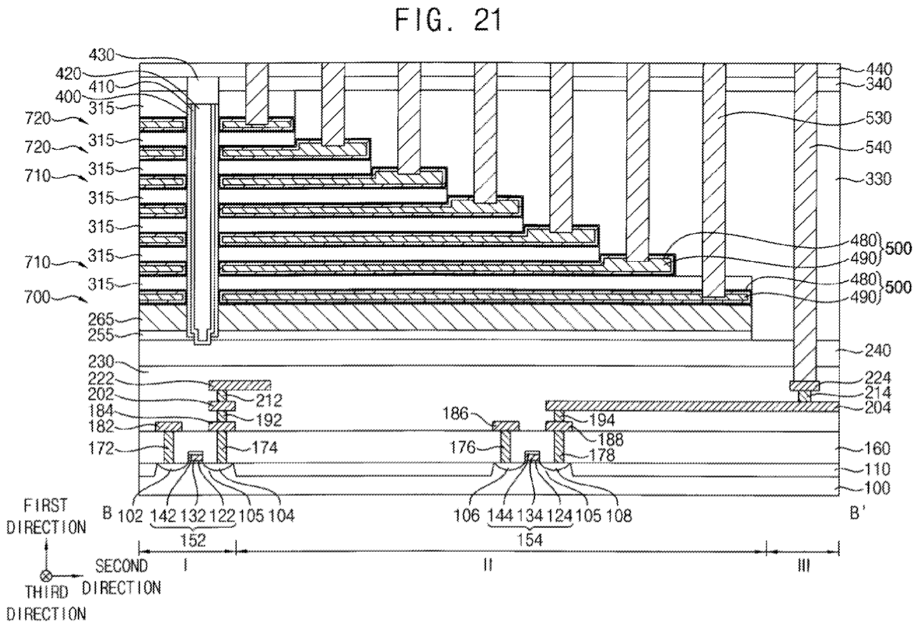

FIGS. 1 to 21 are plan views and cross-sectional views illustrating a method of manufacturing a vertical memory device in accordance with exemplary embodiments of the inventive concept. For example, FIGS. 1, 6, 9, and 19 are plan views, and FIGS. 2 to 5, 7, 8, 10 to 18, 20 and 21 are cross-sectional views.

Hereinafter, a direction substantially vertical to an upper surface of a substrate may be a first direction, and two directions intersecting with each other among horizontal directions substantially parallel to the upper surface of the substrate may be second and third directions, respectively. In exemplary embodiments of the inventive concept, the second and third directions may be orthogonal to each other.

Referring to FIGS. 1 to 3, a circuit pattern may be formed on a substrate 100, and first and second insulating interlayers 160 and 230 covering the circuit pattern may be sequentially formed on the substrate 100.

The substrate 100 may include semiconductor materials, e.g., silicon, germanium, silicon-germanium, etc., or III-V compounds, e.g., GaP, GaAs, GaSb, etc. In exemplary embodiments of the inventive concept, the substrate 100 may be a silicon-on-insulator (SOI) substrate or a germanium-on-insulator (GOI) substrate.

The substrate 100 may be divided into a field region on which an isolation pattern 110 is formed and an active region 105 on which no isolation pattern is formed. The isolation pattern 110 may be formed, e.g., by a shallow trench isolation (STI) process, and may include an oxide, e.g., silicon oxide.

In exemplary embodiments of the inventive concept, the substrate 100 may include first, second and third regions I, II and III. The first region I may be a cell array region in which a memory cell array may be formed, and the second region II may be a pad region in which gate electrode pads may be formed. The cell array region and the pad region may be referred to as a memory cell region, and the third region III may be a peripheral region surrounding the memory cell region. In some cases, the substrate 100 may not include the third region III, and may include only the first and second regions I and II.

In exemplary embodiments of the inventive concept, the vertical memory device may have a cell-over-peri (COP) structure. In other words, the circuit pattern for driving the memory cell may not be formed around the memory cell, but may be formed under the memory cell. Accordingly, a circuit pattern region on which the circuit pattern is formed and the memory cell region may be vertically stacked on the substrate 100. The circuit pattern may also be referred to as a lower circuit pattern.

The circuit pattern may include a transistor, a lower contact plug, a lower wiring, a lower via, and the like. In an exemplary embodiment of the inventive concept, there is formed a first transistor including a first lower gate structure 152 on the first region I of the substrate 100 and first and second impurity regions 102 and 104 at upper portions of the active region 105 adjacent to the first lower gate structure 152. In addition, there is formed a second transistor including a second lower gate structure 154 on the second region II of the substrate 100 and third and fourth impurity regions 106 and 108 at upper portions of the active region 105 adjacent to the second lower gate structure 154.

The first lower gate structure 152 may include a first lower gate insulation pattern 122, a first lower gate electrode 132 and a first lower gate mask 142 sequentially stacked on the substrate 100. The second lower gate structure 154 may include a second lower gate insulation pattern 124, a second lower gate electrode 134 and a second lower gate mask 144 sequentially stacked on the substrate 100.

The first insulating interlayer 160 may be formed on the substrate 100 to cover the first and second transistors, and first, second, third and fourth lower contact plugs 172, 174, 176 and 178 may be formed through the first insulating interlayer 160 to contact the first, second, third and fourth impurity regions 102, 104, 106 and 108, respectively.

First, second, third and fourth lower wirings 182, 184, 186 and 188 may be formed on the first insulating interlayer 160 to contact upper surfaces of the first, second, third and fourth lower contact plugs 172, 174, 176 and 178, respectively. A first lower via 192, a fifth lower wiring 202, a third lower via 212 and a seventh lower wiring 222 may be sequentially stacked on the second lower wiring 184. A second lower via 194, a sixth lower wiring 204, a fourth lower via 214 and a eighth lower wiring 224 may be sequentially stacked on the fourth lower wiring 188.

In exemplary embodiments of the inventive concept, the first to eighth lower wirings 182, 184, 186, 188, 202, 204, 222 and 224, and the first to fourth lower vias 192, 194, 212 and 214 may he formed by a damascene process. Alternatively, the first to eighth lower wirings 182, 184, 186, 188, 202, 204, 222 and 224, and the first to fourth lower vias 192, 194, 212 and 214 may be formed by a patterning process.

The second insulating interlayer 230 may be formed on the first insulating interlayer 160 to cover the first to eighth lower wirings 182, 184, 186, 188, 202, 204, 222 and 224, and the first to fourth lower vias 192, 194, 212 and 214. The first and second insulating interlayers 160 and 230 may include an oxide, e.g., silicon oxide, and thus, may be merged with each other.

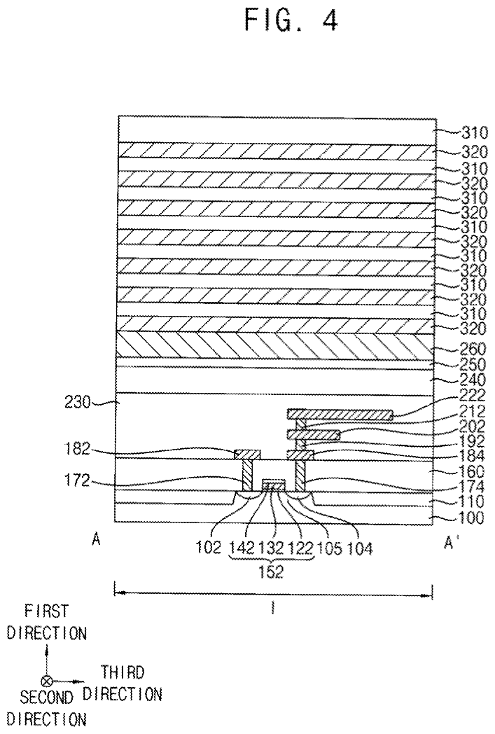

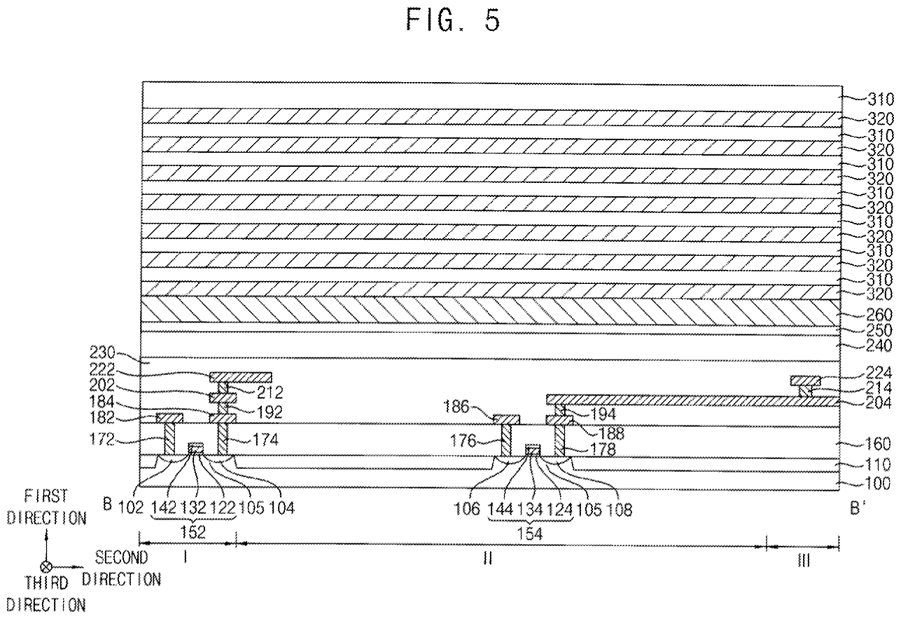

Referring to FIGS. 4 and 5, after sequentially forming a base layer 240, an etch stop layer 250 and a first semiconductor layer 260 on the second insulating interlayer 230, a first sacrificial layer 320 and an insulation layer 310 may be alternately and repeatedly stacked on the first semiconductor layer 260. Accordingly, a mold layer including a plurality of first sacrificial layers 320 and a plurality of insulation layers 310 alternately stacked in the first direction may be formed on the first semiconductor layer 260.

Each of the base layer 240, the etch stop layer 250, the first semiconductor layer 260, the first sacrificial layer 320 and the insulation layer 310 may be formed by a process, e.g., a chemical vapor deposition (CVD) process, an atomic layer deposition (ALD) process, etc.

The base layer 240 may include, e.g., polysilicon, the first semiconductor layer 260 may include, e.g., polysilicon doped with n-type or p-type impurities, and the etch stop layer 250 may include a material having a high etching selectivity with respect to the first semiconductor layer 260, e.g., an oxide such as silicon oxide.

The insulation layer 710 may include an oxide, e.g., silicon oxide, and the first sacrificial layer 320 may include a material having an etching selectivity with respect to the insulation layer 310, e.g., a nitride such as silicon nitride.

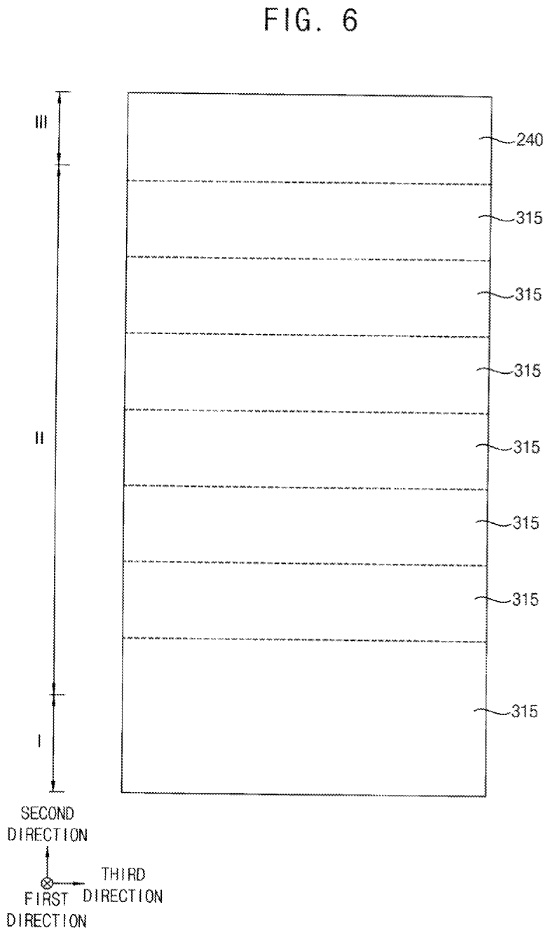

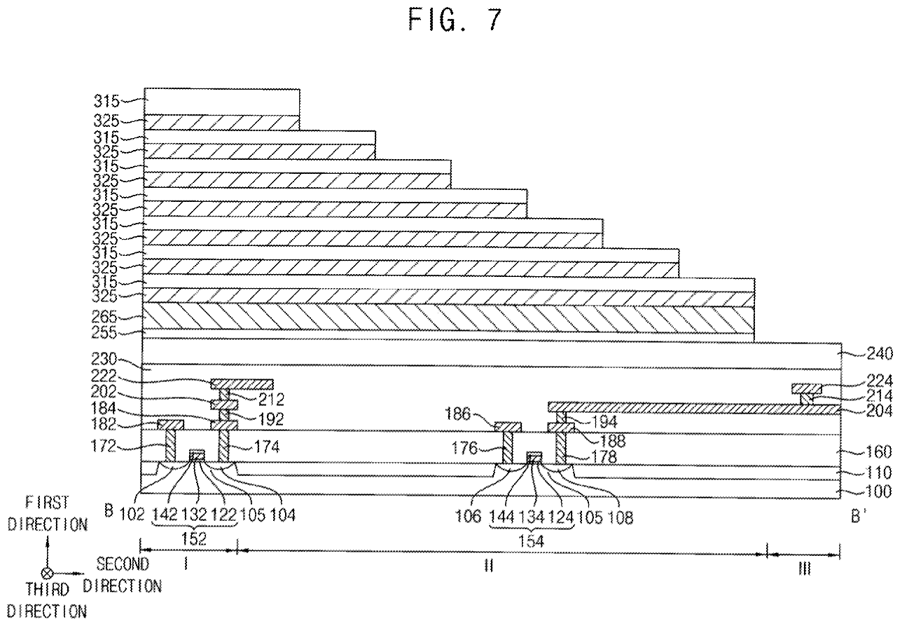

Referring to FIGS. 6 and 7, a photoresist pattern partially covering an uppermost one of the insulation layers 310 may be formed on the uppermost one of the insulation layers 310. The uppermost one of the insulation layers 310 and an uppermost one of the first sacrificial layers 320 thereunder may he etched using the photoresist pattern as an etching mask. Accordingly, a portion of one of the insulation layers 310 directly under the uppermost one of the first sacrificial layers 320 may be exposed.

After reducing an area of the photoresist pattern by a given ratio through a trimming process, the uppermost one of the insulation layers 310, the uppermost one of the first sacrificial layers 320, the exposed one of the insulation layers 310 and one of the first sacrificial layers 320 thereunder may be etched using the reduced photoresist pattern as an etching mask. The trimming process and the etching process may be repeatedly performed so that a mold including a plurality of steps which may include a first sacrificial pattern 325 and an insulation pattern 315 sequentially stacked and having a staircase shape may be formed. Hereinafter, each of the steps may include not only exposed portions, but also portions covered by upper level steps, and thus, may be referred to as an entire portion of the first sacrificial pattern 325 at the same level and an entire portion of the insulation pattern 315 at the same level.

The etch stop layer 250 and the first semiconductor layer 260 may be patterned by the etching process, and may be transformed into an etch stop pattern 255 and a first semiconductor pattern 265, respectively. The etch stop pattern 255 and the first semiconductor pattern 265 may be formed to have an area substantially the same as that of a lowermost step of the mold, the lowermost step including a lowermost one of the first sacrificial patterns 325 and a lowermost one of the insulation patterns 315. In addition, the etch stop pattern 255 and the first semiconductor pattern 265 may form the lowermost step together with the lowermost one of the first sacrificial patterns 325 and the lowermost one of the insulation patterns 315.

The mold may be formed on the first and second regions I and II of the substrate 100. An exposed portion of each step in the mold may be formed on the second region II of the substrate 100.

In exemplary embodiments of the inventive concept, the steps included in the mold may have lengths extending in each of the second and third directions, which may gradually decrease from a lowermost one toward an uppermost one thereof.

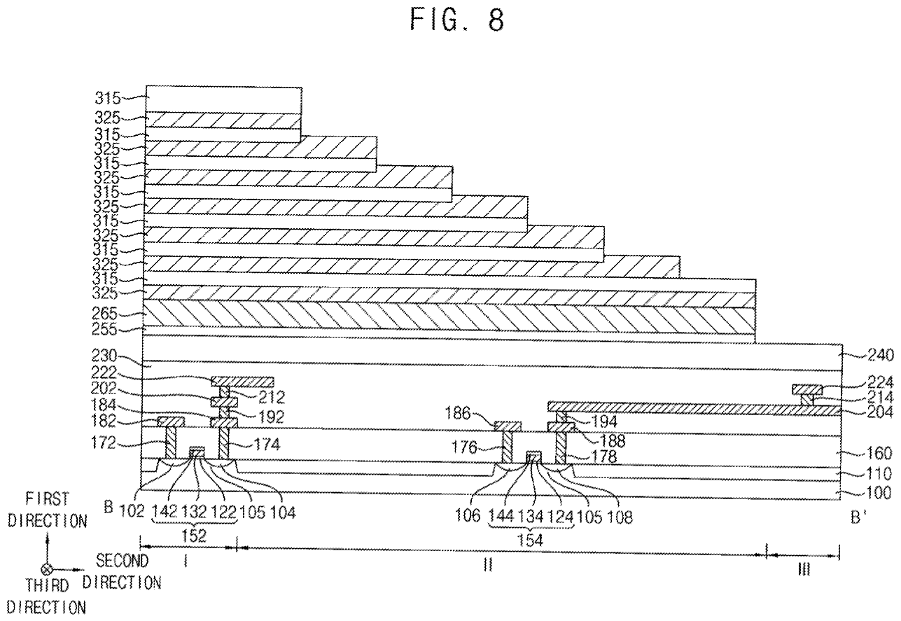

Referring to FIG. 8, a thickness of an end portion in the second direction of at least one of the first sacrificial patterns 325 may be increased.

In an exemplary embodiment of the inventive concept, an end portion of the insulation pattern 315 included in an exposed portion of each of the steps may be removed to expose an end portion of the first sacrificial pattern 325. Afterwards, a material including substantially the same material as that of the first sacrificial pattern 325 may be formed on the exposed end portion of the first sacrificial pattern 325, so that the thickness of the end portion in the second direction of the first sacrificial pattern 325 may be increased. Accordingly, the end portion in the second direction of each of the first sacrificial patterns 325 may have an upper surface higher than the unexposed portions of the first sacrificial patterns 325.

FIG. 8 shows increased thicknesses of the end portions of all first sacrificial patterns 325 except for a lowermost one and an uppermost one; however, the inventive concept is not limited thereto. For example, the thicknesses of the end portions of all of the first sacrificial patterns 325 may be increased.

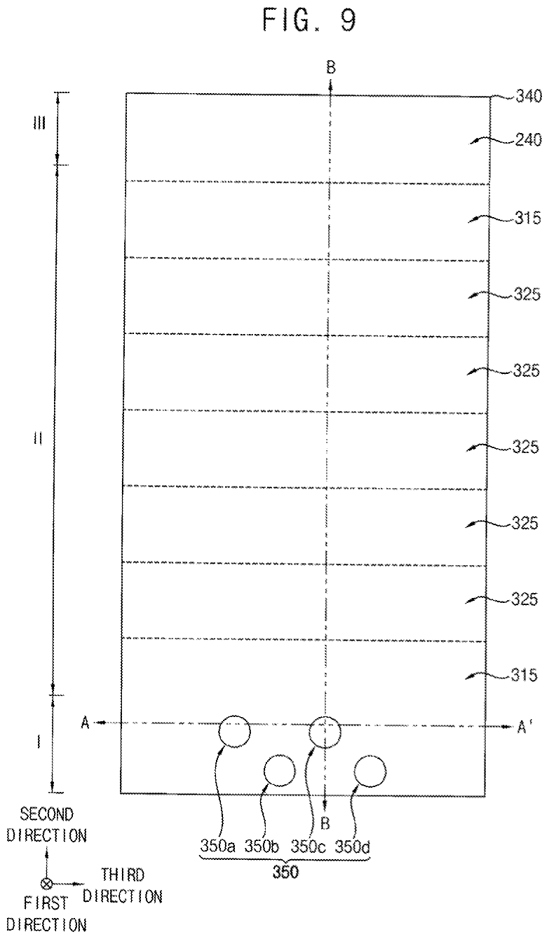

Referring to FIGS. 9 to 11, a third insulating interlayer 330 may be formed on the base layer 240 to cover the mold, and the third insulating interlayer 330 may be planarized until an upper surface of the uppermost one of the insulation patterns 315 may be exposed. Accordingly, the third insulating interlayer 330 may cover a sidewall of the mold. The planarization process may include, e.g., a chemical mechanical polishing (CMP) process and/or an etch back process. The third insulating interlayer 330 may be merged with the insulation pattern 315.

A fourth insulating interlayer 340 may be formed on an upper surface of the mold and an upper surface of the third insulating interlayer 330, a first mask may be formed on the fourth insulating interlayer 340, and the insulation patterns 315 and the first sacrificial patterns 325 may be etched using the first mask as an etching mask to form a first channel hole 350 extending through the fourth insulating interlayer 340, the insulation patterns 315 and the first sacrificial patterns 325, which may expose an upper surface of the first semiconductor pattern 265.

A plurality of first channel holes 350 may be formed in each of the second and third directions to define a channel hole array. In an exemplary embodiment of the inventive concept, the channel hole array may include a plurality of channel hole blocks spaced apart from each other in the third direction, and each of the channel hole blocks may include first, second, third and fourth channel hole columns 350a, 350b, 350c and 350d sequentially arranged in the third direction.

In the etching process, each of the first channel holes 350 may extend through a portion of the first semiconductor pattern 265, and the first channel holes 350 may have depth distribution in the first direction toward the upper surface of the substrate 100. In other words, the depths of the first channel holes 350 may be different from each other.

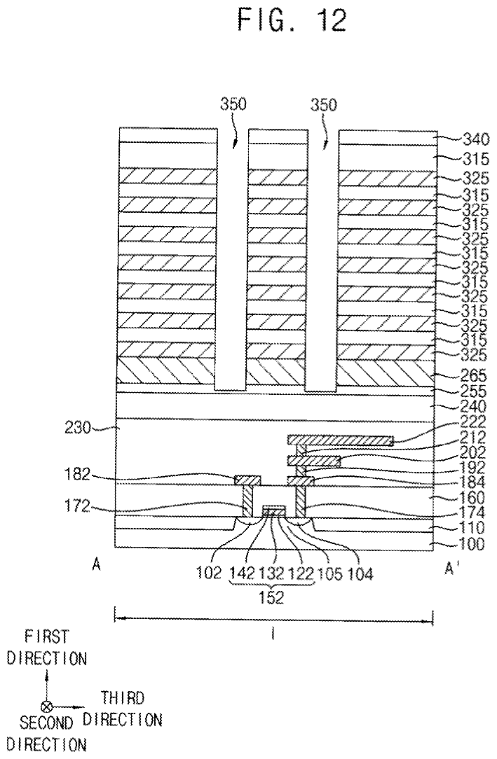

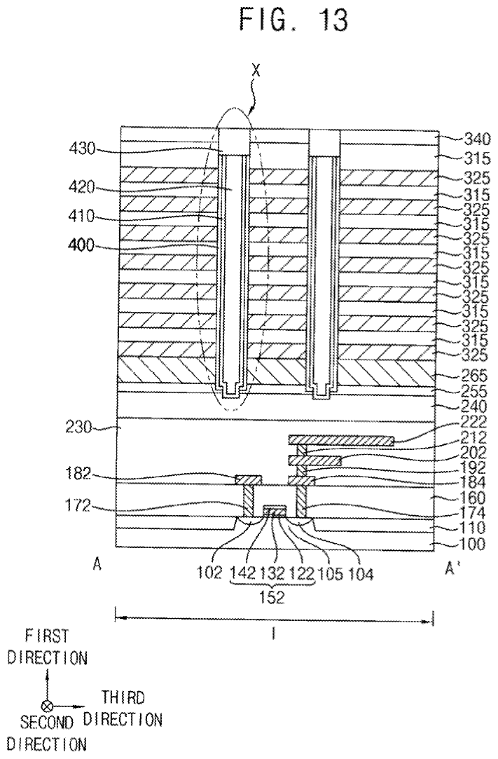

Referring to FIG. 12, a portion of the first semiconductor pattern 265 exposed by each of the first channel holes 350 may be further etched to expose an upper surface of the etch stop pattern 255 thereunder.

Accordingly, the first channel holes 350 may extend through the first semiconductor pattern 265 to expand in the first direction, and may have substantially the same depth in the first direction due to the etch stop pattern 255 which includes a material having a high etching selectivity with respect to the first semiconductor layer 260.

Referring to FIGS. 13 to 15, after removing the first mask, a first blocking layer, a first charge storage layer, a first tunnel insulation layer and a first spacer layer may be sequentially formed on sidewalls of the first channel holes 350, the exposed upper surface of the etch stop pattern 255 and an upper surface of the fourth insulating interlayer 340. In this case, the first spacer layer may be anisotropically etched to form a first spacer only remaining on the sidewalls of the first channel holes 350. Then, the first tunnel insulation layer, the first charge storage layer, the first blocking layer and the etch stop pattern 255 may be etched using the first spacer as an etching mask to form a first tunnel insulation pattern 390, a first charge storage pattern 380 and a first blocking pattern 370 on the sidewalls of the first channel holes 350 to have a cup-like shape of which a central lower surface is opened on the base layer 240. During the etching process, an upper portion of the base layer 240 may also be partially removed.

The first tunnel insulation pattern 390 and the first blocking pattern 370 may include an oxide, e.g., silicon oxide, and the first charge storage pattern 380 may include a nitride, e.g., silicon nitride. The first tunnel insulation pattern 390, the first charge storage pattern 380 and the first blocking pattern 370 sequentially stacked on the sidewalls of the first channel holes 350 in a horizontal direction substantially parallel to the upper surface of the substrate 100 may form a first charge storage structure 400.

After removing the first spacer, a first channel layer may be formed on the exposed base layer 240, the first tunnel insulation pattern 390 and the fourth insulating interlayer 340, and a first filling layer which may sufficiently fill remaining portions of the first channel holes 350 may be formed on the first channel layer.

The first filling layer and the first channel layer may be planarized until an upper surface of the fourth insulating interlayer 340 may be exposed so that a first filling pattern 420 may fill the remaining portion of each of the first channel holes 350, and thus, the first channel layer may he transformed into a first channel 410. Accordingly, the first charge storage structure 400, the first channel 410 and the first filling pattern 420 may be sequentially stacked on the base layer 240 which is exposed by each of the first channel holes 350.

The first channel 410 may include, e.g., doped or undoped polysilicon or single crystalline silicon, and the first filling pattern 420 may include an oxide, e.g., silicon oxide.

The first channel holes 350 in which the first channels 410 are formed, respectively, may define the channel hole block including the first to fourth channel hole columns 350a, 350b, 350c and 350d, and a plurality of channel blocks may define the channel hole array. In other words, the first channels 410 may also define a channel block and a channel array.

An upper portion of a first structure including the first filling pattern 420, the first channel 410 and the first charge storage structure 400 may be removed to form a trench, and a first capping pattern 430 may be formed to fill the trench.

For example, after removing the upper portion of the first structure by an etch back process to form the trench, a first capping layer filling the trench may be formed on the first structure and the fourth insulating interlayer 340, and an upper portion of the first capping layer may be planarized until the upper surface of the fourth insulating interlayer 340 may be exposed to form the first capping pattern 430. The first capping pattern 430 may include, e.g., doped or undoped polysilicon or single crystalline silicon.

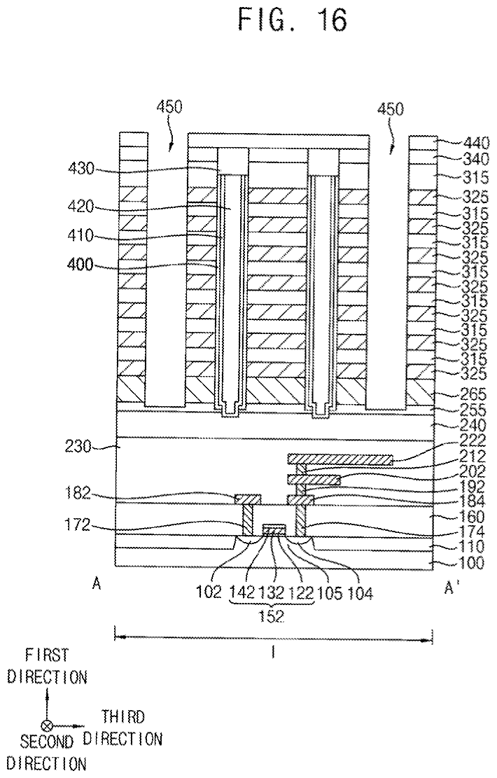

Referring to FIG. 16, a fifth insulating interlayer 440 may be formed on the fourth insulating interlayer 340 and the first capping pattern 430, a second mask may be formed on the fifth insulating interlayer 440, and an opening 450 may be formed through the fourth and fifth insulating inter:layers 340 and 440, the insulation patterns 315, the first sacrificial patterns 325 and the first semiconductor pattern 265 to expose an upper surface of the etch stop pattern 255.

In exemplary embodiments of the inventive concept, like the first channel hole 350, the opening 450 may be formed by performing a first etching process to expose the fourth and fifth insulating interlayers 340 and 440, the insulation patterns 315, the first sacrificial patterns 325, and a portion of the first semiconductor pattern 265, and by performing a second etching process to enlarge a lower portion of the opening 450 so that the upper surface of the etch stop pattern 255 may be exposed.

The opening 450 may extend in the second direction between the channel blocks on the first and second regions I and II, and thus, a plurality of openings 450 may be formed in the third direction. In other words, one channel block including four channel columns therein may be formed between two neighboring openings 450. However, the inventive concept may not be hunted thereto.

The fifth insulating interlayer 440 may be merged with the fourth insulating interlayer 340 thereunder.

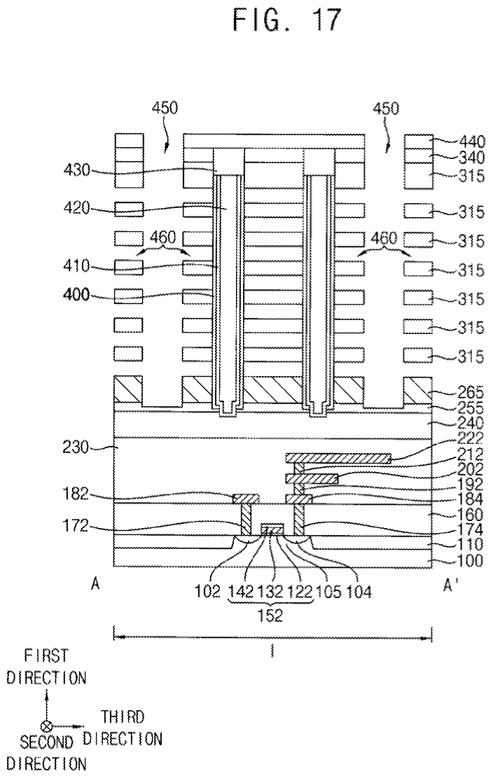

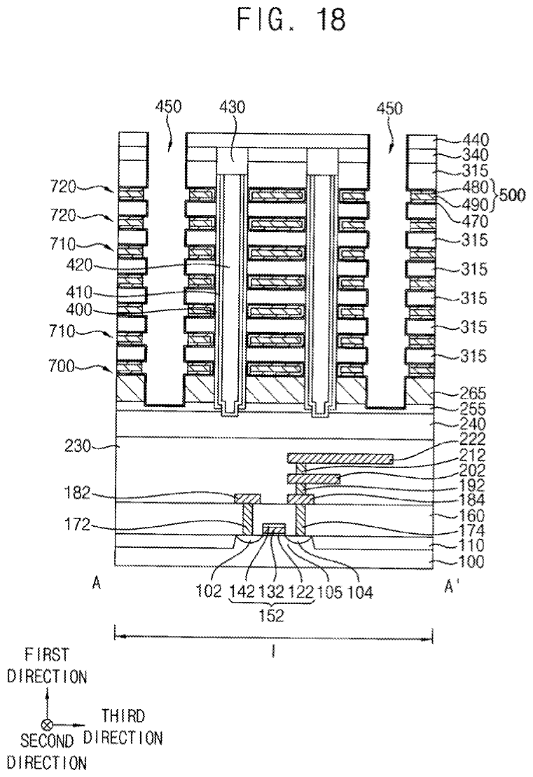

Referring to FIG. 17, after removing the second mask, the first sacrificial patterns 325 exposed by the openings 450 may be removed to form a first gap 460 between the insulation patterns 315 at neighboring levels, and a portion of an outer sidewall of the first blocking pattern 370 may be exposed by the first gap 360, in exemplary embodiments of the inventive concept, the first sacrificial patterns 325 exposed by the openings 450 may be removed by a wet etching process using an etchant including phosphoric acid or sulfuric acid.

Referring to FIG. 18, a second blocking layer 470 may be formed on sidewalls of the openings 450, the exposed outer sidewall of the first blocking pattern 370, inner sidewalls of the first gaps 460, surfaces of the insulation patterns 315, the exposed upper surface of the etch stop pattern 255 and an upper surface of the fifth insulating interlayer 440. In addition, a barrier layer may be formed on the second blocking layer 470, and a first conductive layer, which may fill remaining portions of the first gaps 460 and may cover the sidewall of the openings 450, may be formed on the barrier layer.

Portions of the first conductive layer and the barrier layer on the sidewalls of the openings 450 and in the first gaps 460 adjacent thereto may be removed to form a gate electrode 500 including a first conductive pattern 490 and a barrier pattern 480 covering upper and lower surfaces and a sidewall of the first conductive pattern 490 facing the first channel 410. Upper and lower surfaces and a sidewall of the gate electrode 500 facing the first channel 410 may be covered by the second blocking layer 470.

In exemplary embodiments of the inventive concept, the first conductive layer and the barrier layer may be partially removed by a wet etching process. The second blocking layer 470 may include a metal oxide, e.g., aluminum oxide, the first conductive pattern 490 may include a low resistance metal, e.g., tungsten, titanium, tantalum, platinum, etc., and the barrier layer, e.g., the barrier pattern 480, may include a metal nitride, e.g., titanium nitride, tantalum nitride, etc.

In exemplary embodiments of the inventive concept, the gate electrode 500 may extend in the second direction on the first and second regions I and II of the substrate 100, and a plurality of gate electrodes 500 may be formed in the third direction. In other words, the gate electrodes 500 each of which may extend in the second direction may be spaced apart from each other in the third direction by the opening 450.

In addition, a plurality of gate electrodes 500 may be sequentially stacked to be spaced apart from each other in the first direction, and may form a gate electrode structure. Extension lengths in the second direction of the gate electrodes 500 may gradually decrease from an uppermost one of the gate electrodes 500 toward a lowermost one of the gate electrodes 500, and thus, the gate electrodes 500 may have a staircase shape. Each of the gate electrodes 500 may include a pad on opposite ends thereof in the second direction, and the pad of at least one of the gate electrodes 500 may protrude in the first direction and have a greater thickness than the pad of another one of the gate electrodes 500.

The gate electrodes 500 may include first, second and third gate electrodes sequentially stacked in the first direction, and the first to third gate electrodes may serve as a ground selection line (GSL) 700, a word line 710 and a string selection line (SSL) 720, respectively. Each of the first to third gate electrodes may be formed at one level or a plurality of levels. In exemplary embodiments of the inventive concept, the first gate electrode may be formed at a lowermost level, the third gate electrode may be formed at an uppermost level and a level directly under the uppermost level, and the second gate electrode may he formed at a plurality of levels between the first gate electrode and the third gate electrode.

In exemplary embodiments of the inventive concept, the second gate electrode may solely serve as the word line 710, and the third gate electrode may solely serve as the SSL 720. It is to be understood, however, that the first gate electrode and the first semiconductor pattern 265 thereunder including doped polysilicon may serve as the GSL 700.

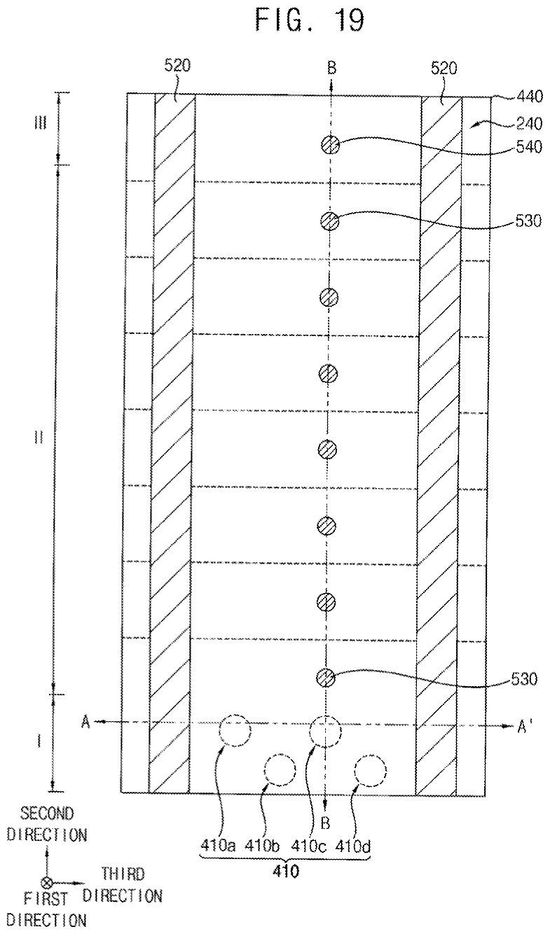

Referring, to FIGS. 19 to 21, after forming a fifth impurity region 245 at an upper portion of the base layer 240 under the opening 450, a second spacer 510 may be formed on each of opposite sidewalls in the third direction of the opening 450, and a common source line (CSL) 520 may be formed to fill a remaining portion of the opening 450.

For example, a second spacer layer may be formed on each of the opposite sidewalls of the opening 450, the second blocking layer 470 and the fifth insulating interlayer 440, the second spacer layer may be anisotropically etched to form the second spacer 510 on each of the opposite sidewalk of the opening 450, and a portion of the second blocking layer 470 and a portion of the etch stop pattern 255 thereunder may be removed using the second spacer 510 as an etching mask to expose an upper surface of the base layer 240. After forming a second conductive layer on the exposed upper surface of the base layer 240, the second spacer 510 and the fifth insulating interlayer 440, the second conductive layer may be planarized until an upper surface of the fifth insulating interlayer 440 is exposed to form the CSL 520.

The second spacer 510 may include an oxide, e.g., silicon oxide, and the CSL 520 may include a metal, e.g., tungsten. The fifth impurity region 245 may be formed by doping n-type impurities or p-type impurities.

In exemplary embodiments of the inventive concept, the CSL 520 may extend in the second direction to divide the gate electrode 500 at the same level into two pieces; however, a sidewall of the CSL 520 may be covered by the second spacer 510 to be insulated from the gate electrode 500. The CSL 520 may contact an upper surface of the fifth impurity region 245 at the upper portion of the base layer 240 to be electrically connected thereto.

First contact plugs 530 may be formed through the third, fourth and fifth insulating interlayers 330, 340 and 440 to contact the pads of gate electrodes 500, respectively, and a second contact plug 540 may be formed through the second, third, fourth and fifth insulating interlayers 230, 330, 340 and 440 and the base layer 240 to contact the eighth lower wiring 224.

The first contact plugs 530 may be formed by forming contact holes through the third, fourth and fifth insulating interlayers 330, 340 and 440 to expose upper surfaces of the pads of the gate electrodes 500, forming a second conductive layer to fill the contact holes, and planarizing the second conductive layer until the upper surface of the fifth insulating interlayer 440 is exposed.

The first and second contact plugs 530 and 540 may include a metal, e.g., tungsten, and may further include a barrier layer including, e.g., a metal nitride.

A third contact plug contacting an upper surface of the first capping pattern 430, a bit line contacting the third contact plug, a fourth contact plug contacting an upper surface of the CSL 520, and an upper wiring may be further formed to complete the fabrication of the vertical memory device.

As described above, in the vertical memory device having the COP structure in which the circuit pattern may be formed under the memory cell array, the etch stop pattern 225 and the first semiconductor pattern 265 may be formed on the base layer 240 including polysilicon, and the mold including the first sacrificial patterns 325 and the insulation patterns 315 may be formed on the first semiconductor pattern 265. Accordingly, each of the first channel holes 350 in which the first channels 410 are formed may have a constant depth on the upper surface of the etch stop pattern 225, so that a current applied to the first channels 410 may have a constant value. As shown in FIG. 19, there is provided a plurality of first channels 410a, 410b, 410c and 410b.

The GSL 700 may include not only the first semiconductor pattern 265 including doped polysilicon, but also the first gate electrode including a metal on the first semiconductor pattern 265, and thus, the GSL 700 may have a relatively low resistance when compared to a GSL including only the first semiconductor pattern 265. If a GSL includes only the first semiconductor pattern 265, the contact hole in which the first contact plug 530 is formed may extend through the GSL to a lower structure under the GSL. However, in exemplary embodiments of the inventive concept, the GSL 700 may further include the first gate electrode including a metal on the first semiconductor pattern 265, and thus, when the contact hole is formed, the etching process may be terminated at the first gate electrode, and not extend through the GSL 700.

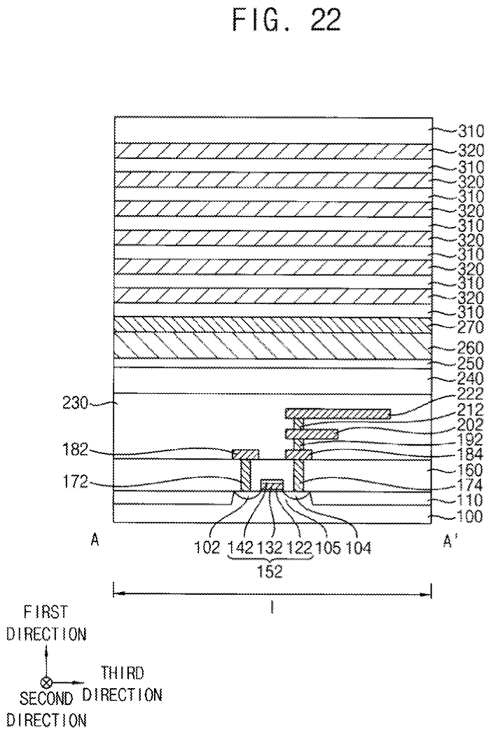

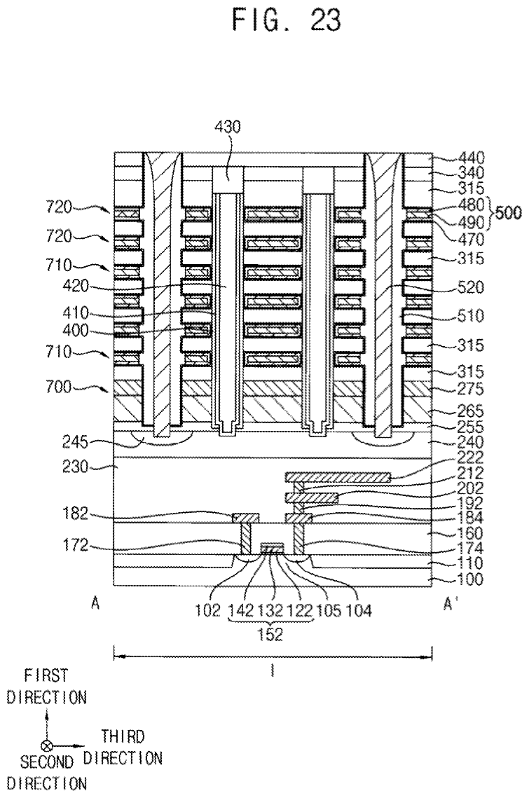

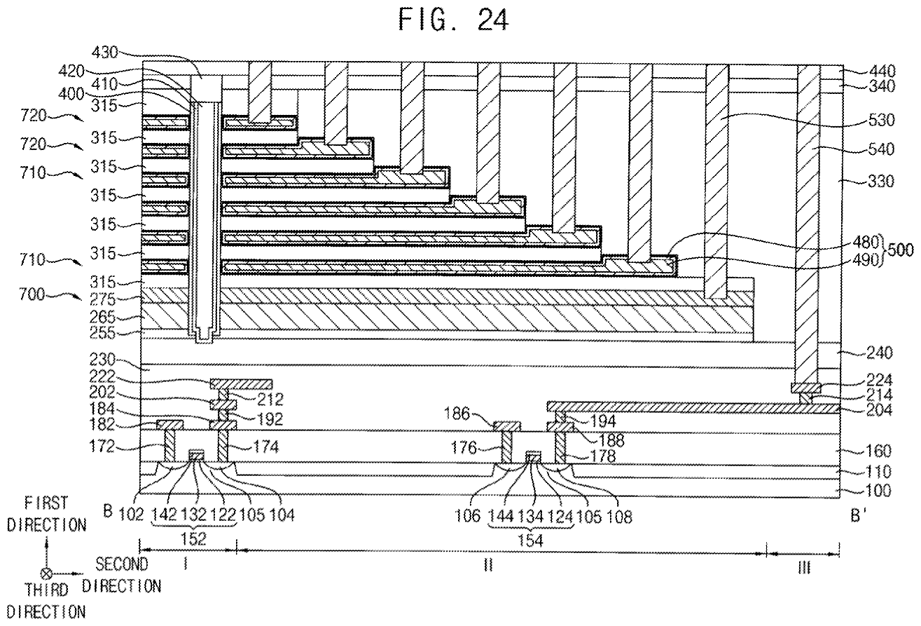

FIGS. 22, 23 and 24 are cross-sectional views illustrating a method of manufacturing vertical memory device. For example, FIGS. 22 and 23 are cross-sectional views taken along lines A-A′ of FIG. 1, and FIG. 24 is cross-sectional view taken along a line B-B′ of FIG. 1.

This method of manufacturing the vertical memory device may include processes substantially the same as or similar to the processes described with reference to FIGS. 1 to 21. Accordingly, like reference numerals refer to like elements, and thus, detailed descriptions thereof may be omitted.

Referring to FIG. 22, processes substantially the same as or similar to the processes described with reference to FIGS. 1 to 5 may be performed.

However, a first metal layer 270 may further formed on the first semiconductor layer 250. The first metal layer 270 may include a metal, e.g., tungsten, or a metal silicide, e.g., tungsten silicide.

Referring to FIGS. 23 and 24, processes substantially the same as or similar to the processes described with reference to FIGS. 1 to 5 may be performed to complete the fabrication of the vertical memory device.

The GSL 700 of the vertical memory device may include the first semiconductor pattern 265 and a first metal pattern 275. Accordingly, the GSL 700 may have a relatively low resistance when compared to a GSL including only the first semiconductor pattern 265.

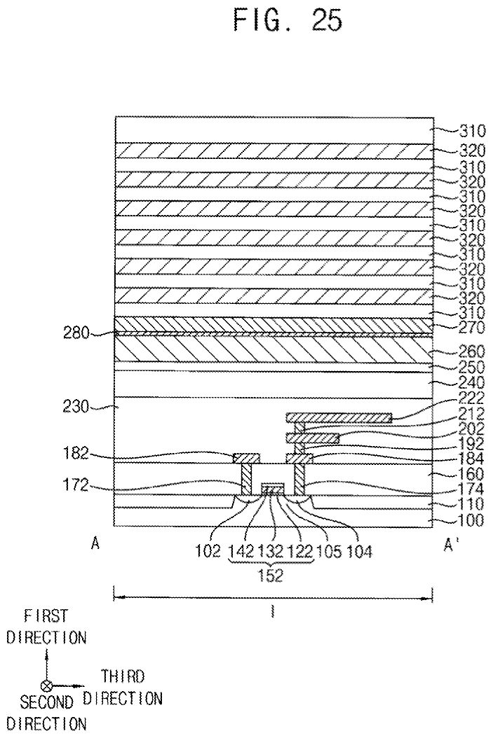

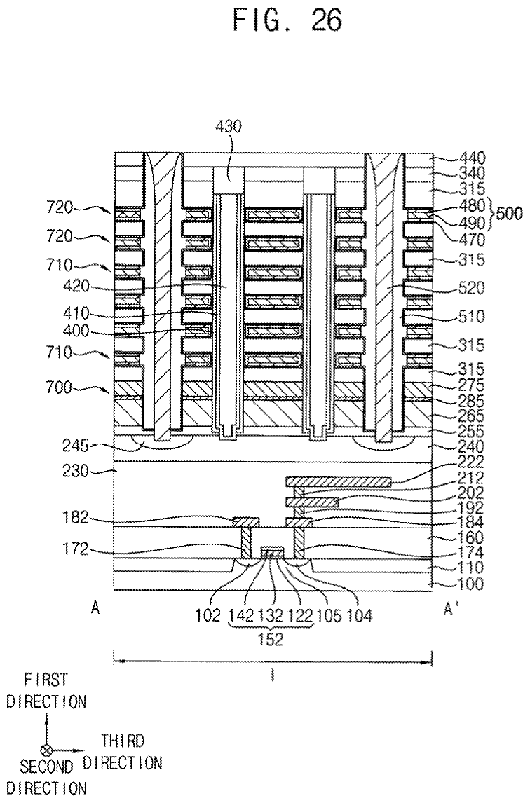

FIGS. 25 and 26 are cross-sectional views taken along lines A-A′ of FIG. 1 illustrating a method of manufacturing a vertical memory device in accordance with exemplary embodiments of the inventive concept.

This method of manufacturing the vertical memory device may include processes substantially the same as or similar to the processes described with reference to FIGS. 22 to 24. Accordingly, like reference numerals refer to like elements, and thus, detailed descriptions thereof may be omitted.

Referring to FIG. 25, processes substantially the same as or similar to the processes described with reference to FIG. 22 may be performed.

However, a second metal layer 280 may be formed between the first semiconductor layer 260 and the first metal layer 270. Like the first metal layer 270, the second metal layer 280 may include, a metal, e.g., tungsten, or a metal silicide, e.g., tungsten silicide.

In exemplary embodiments of the inventive concept, the first metal layer 270 may include, e.g., tungsten, and the second metal layer 280 may include, e.g., tungsten silicide.

Referring to FIG. 26, processes substantially the same as or similar to the processes described with reference to FIGS. 23 and 24 may be performed to complete the fabrication of the vertical memory device.

The GSL 700 of the vertical memory device may include the first semiconductor pattern 265, a second metal pattern 285, and the first metal pattern 275. Accordingly, the GSL 700 may have a relatively low resistance when compared to a GSL including only the first semiconductor pattern 265.

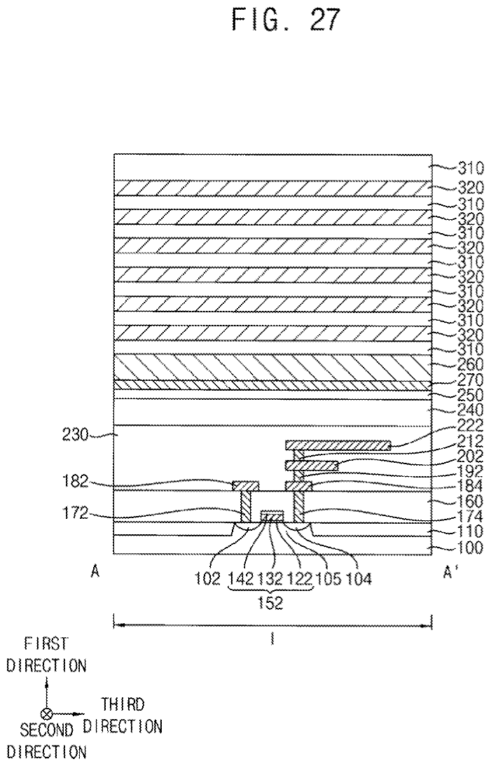

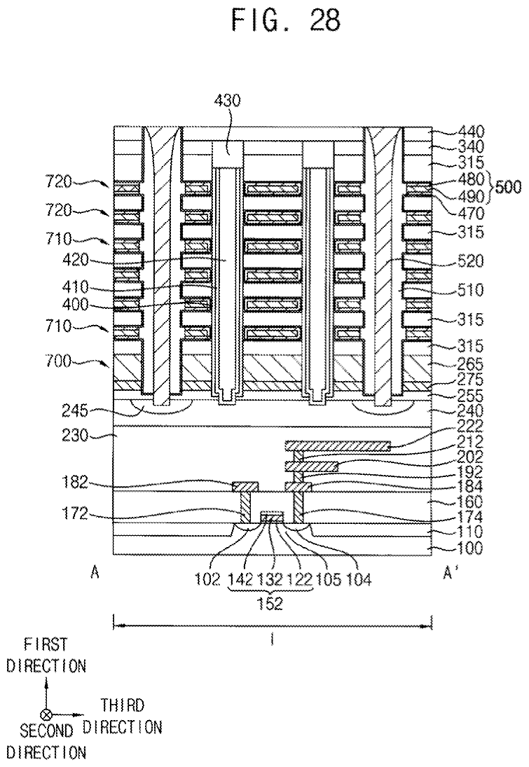

FIGS. 27 to 29 are cross-sectional views illustrating a method of manufacturing a vertical memory device in accordance with exemplary embodiments of the inventive concept. For example, FIGS. 27 and 28 are cross-sectional views taken along lines A-A′ of FIG. 1, and FIG. 27 is cross-sectional view taken along a line B-B′ of FIG. 1.

This method of manufacturing the vertical memory device may include processes substantially the same as or similar to the processes described with reference to FIGS. 1 to 21. Accordingly, like reference numerals refer to like elements, and thus, detailed descriptions thereof may be omitted.

Referring to FIG. 27, processes substantially the same as or similar to the processes described with reference to FIGS. 1 to 5 may be performed.

However, a first metal layer 270 may be formed under the first semiconductor layer 260. The first metal layer 270 may include a metal, e.g., tungsten, or a metal silicide, e.g., tungsten silicide.

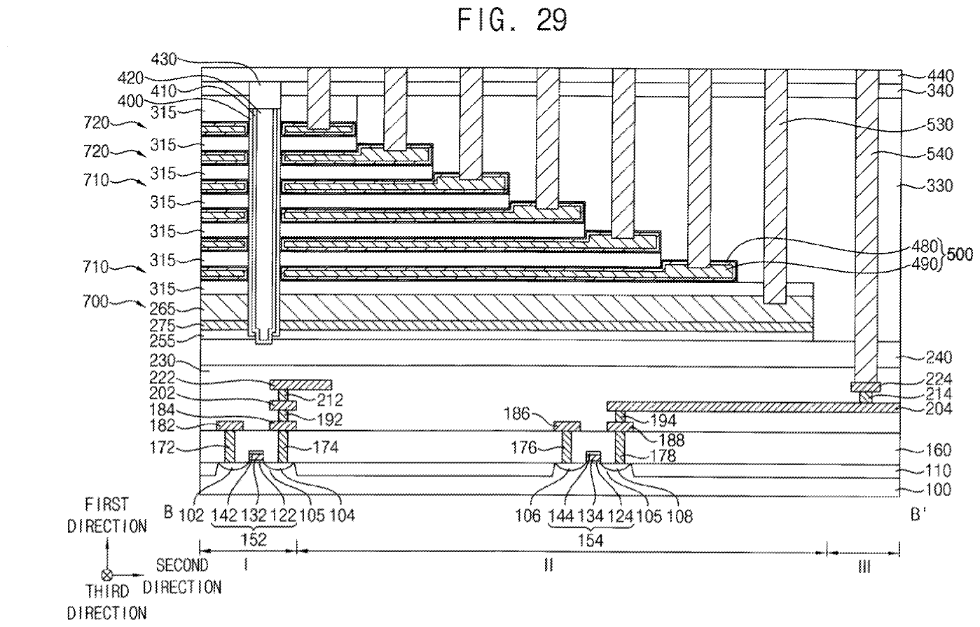

Referring to FIGS. 28 and 29, processes substantially the same as or similar to the processes described with reference to FIGS. 6 to 21 may be performed to complete the fabrication of the vertical memory device.

The GSL 700 of the vertical memory device may include a first metal pattern 275 and the first semiconductor pattern 265 sequentially stacked. Accordingly, the GSL 700 may have a relatively low resistance when compared to a GSL including only the first semiconductor pattern 265.

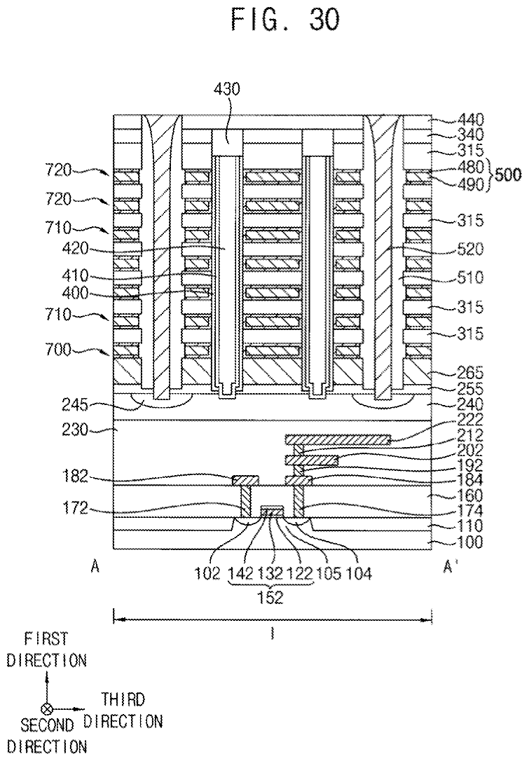

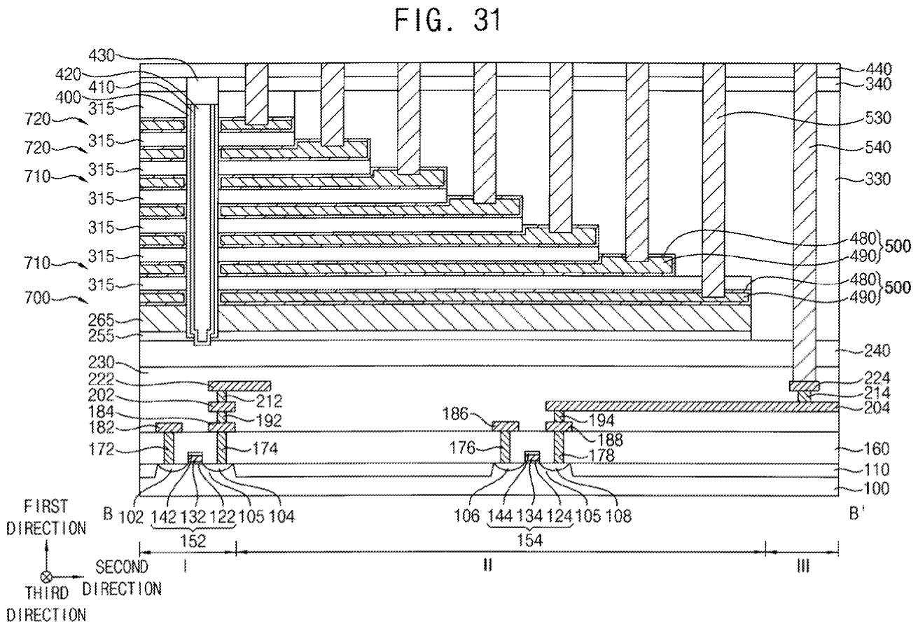

FIGS. 30 and 31 are cross-sectional views illustrating a method of manufacturing a vertical memory device in accordance with exemplary embodiments of the inventive concept. For example, FIG. 30 is a cross-sectional view taken along a line A-A′ of FIG. 1, and FIG. 31 is a cross-sectional view taken along a line B-B′ of FIG. 1.

This vertical memory device may be substantially the same as or similar to the vertical memory device described with reference to FIGS. 19 to 21, except that it does not include the second blocking layer. Accordingly, like reference numerals refer to like elements, and thus, detailed descriptions thereof may be omitted.

Referring to FIGS. 30 and 31, the vertical memory device may not include the second blocking layer 470, and thus, an upper surface of the first semiconductor pattern 265 and a lower surface of the first gate electrode forming the GSL 700 may contact each other.

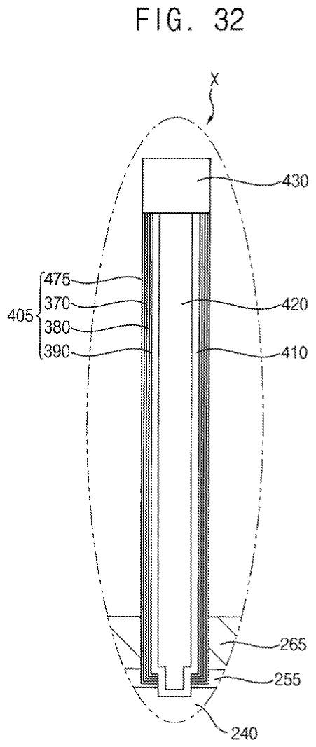

FIG. 32 is cross-sectional view illustrating a vertical memory device in accordance with exemplary embodiments of the inventive concept. For example, FIG. 32 is an enlarged cross-sectional view of a region X like that shown in FIG. 13.

This vertical memory device may be substantially the same as or similar to the vertical memory device described with reference to FIGS. 30 and 31, except that it includes a second charge storage structure instead of the first charge storage structure. Accordingly, like reference numerals refer to like elements, and thus, detailed descriptions thereof may be omitted.

Referring to FIG. 32, a second charge storage structure 405 on a sidewall of the first channel hole 350 may include a second blocking pattern 475, the first blocking pattern 370 the first charge storage pattern 380 and the first tunnel insulation pattern 390 sequentially stacked.

In other words, the second blocking pattern 475 may be formed on the sidewall of the first channel hole 350.

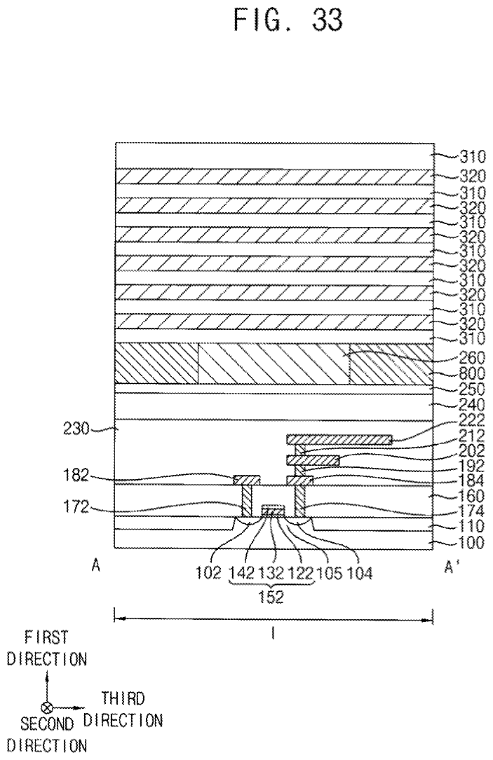

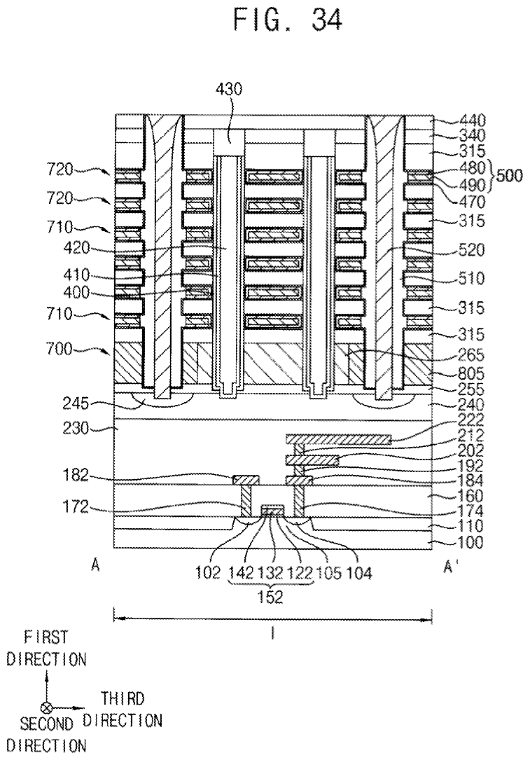

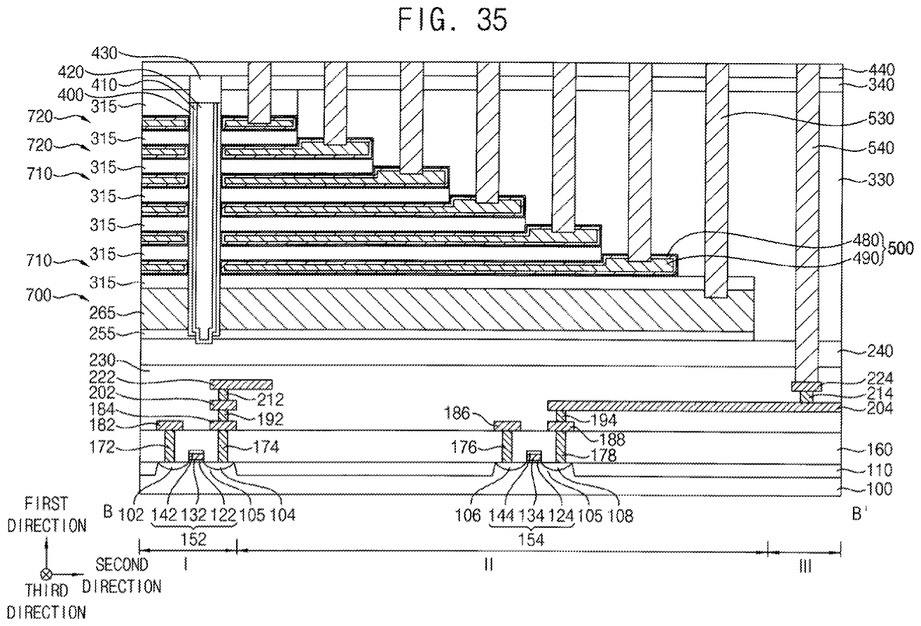

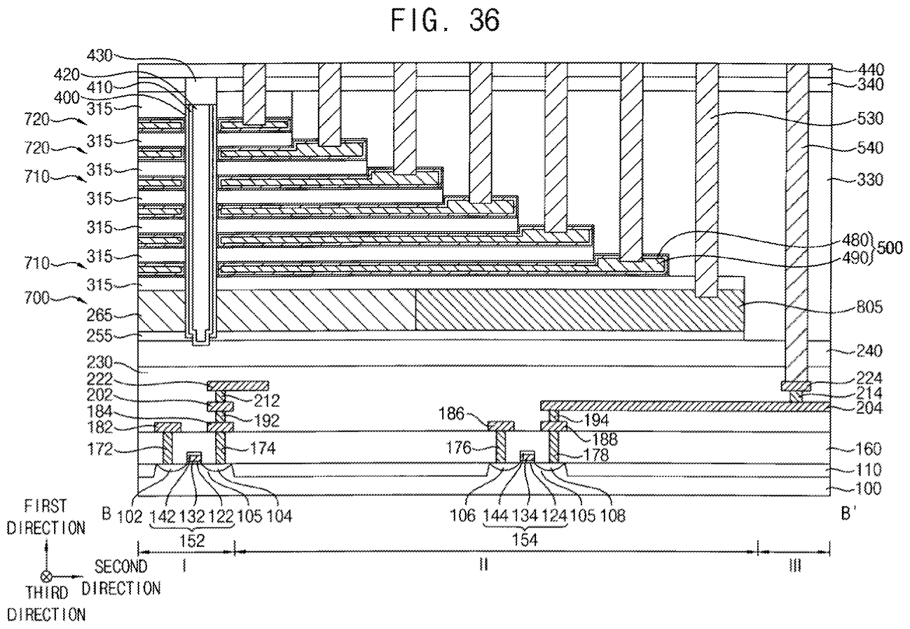

FIGS. 33 to 36 are cross-sectional views illustrating a method of manufacturing a vertical memory device in accordance with exemplary embodiments of the inventive concept. For example, FIGS. 33 and 34 are cross-sectional views taken along lines A-A′ of FIG. 1, and FIGS. 35 and 36 are cross-sectional views taken along lines B-B′ of FIG. 1.

This method of manufacturing the vertical memory device may include processes substantially the same as or similar to the processes described with reference to FIGS. 1 to 21. Accordingly, like reference numerals refer to like elements, and thus, detailed descriptions thereof may be omitted.

Referring to FIG. 33, processes substantially the same as or similar to the processes described with reference to FIGS. 1 to 5 may be performed.

However, the first semiconductor layer 260 and a third metal layer 800 may be formed horizontally on the etch stop layer 250. In an exemplary embodiment of the inventive concept, each of the first semiconductor layer 260 and the third metal layer 800 may extend in the second direction, and a plurality of first semiconductor layers 260 and a plurality of third metal layers 800 may be alternately arranged in the third direction. The third metal layer 800 may be overlapped with each of the openings 450 subsequently formed, and the first semiconductor layer 260 may be overlapped with the first channels 410 between the openings 450.

The third metal layer 800 may include a metal, e.g., tungsten, or a metal silicide, e.g., tungsten silicide.

Referring to FIGS. 34 and 35, processes substantially the same as or similar to the processes described with reference to FIGS. 6 to 21 may be performed to complete the fabrication of the vertical memory device.

The GSL 700 of the vertical memory device may include the first semiconductor pattern 265 and a third metal pattern 805. Accordingly, the GSL 700 may have a relatively low resistance when compared to a GSL including only the first semiconductor pattern 265. In an exemplary embodiment of the inventive concept, the third metal pattern 805 may extend in the second direction to be adjacent to the CSL 520 in the opening 450, sidewalls of the first semiconductor pattern 265 and the third metal pattern 805 may contact each other, and the first semiconductor pattern 265 may extend in the second direction to be adjacent to lower portions of the first channels 410.

FIG. 36 is a cross-sectional view taken along a line B-B′ of FIG. 1 illustrating a vertical memory device in accordance with exemplary embodiments of the inventive concept.

This vertical memory device may he substantially the same as or similar to the vertical memory device described with reference to FIGS. 34 and 35, except for the shape of the third metal pattern. Accordingly, like reference numerals refer to like elements, and thus, detailed descriptions thereof may be omitted.

Referring to FIG. 36, the third metal pattern 805 may contact not only the sidewall of the first semiconductor pattern 265 in the third direction, but also each of opposite end portions of the first semiconductor pattern 265 in the second direction. In other words, the first semiconductor pattern 265 may extend in the second direction, but may not extend to each of opposite end portions of the mold. In addition, the first semiconductor pattern 265 may be arranged in plural in the third direction. The third metal pattern 805 may include a plurality of first portions that may extend in the second direction and may be spaced apart from each other in the third direction. In addition, the third metal pattern 805 may include a second portion that may be formed on each of the opposite end portions of the mold to connect the first portions with each other and may contact each of the opposite end portions of the first semiconductor patterns 265.

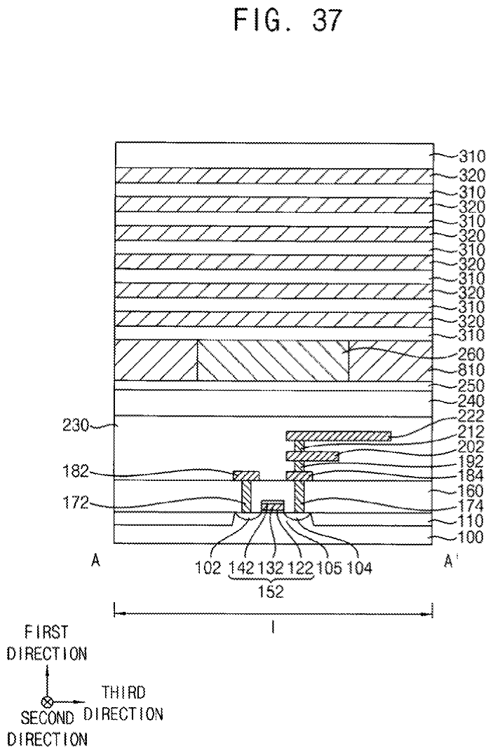

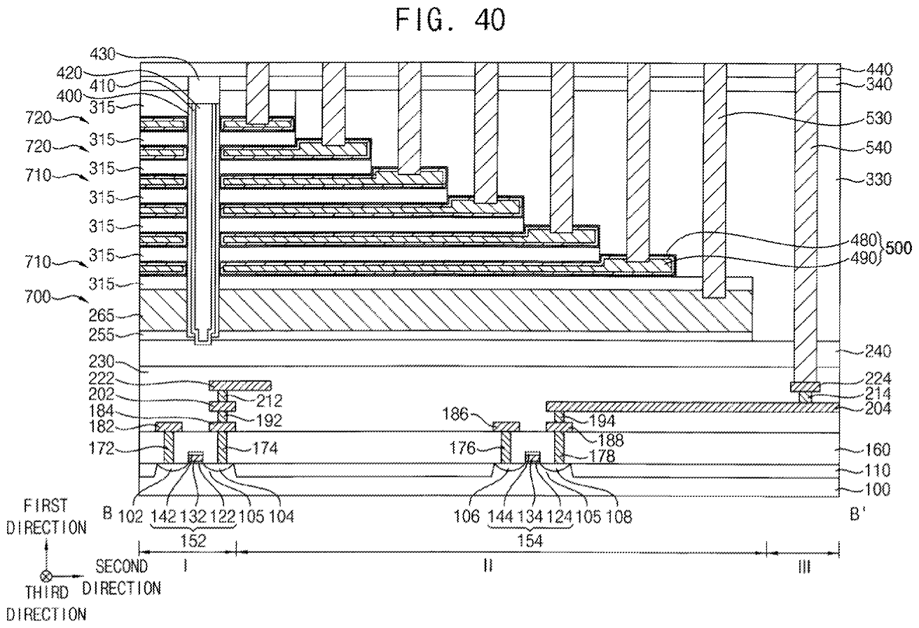

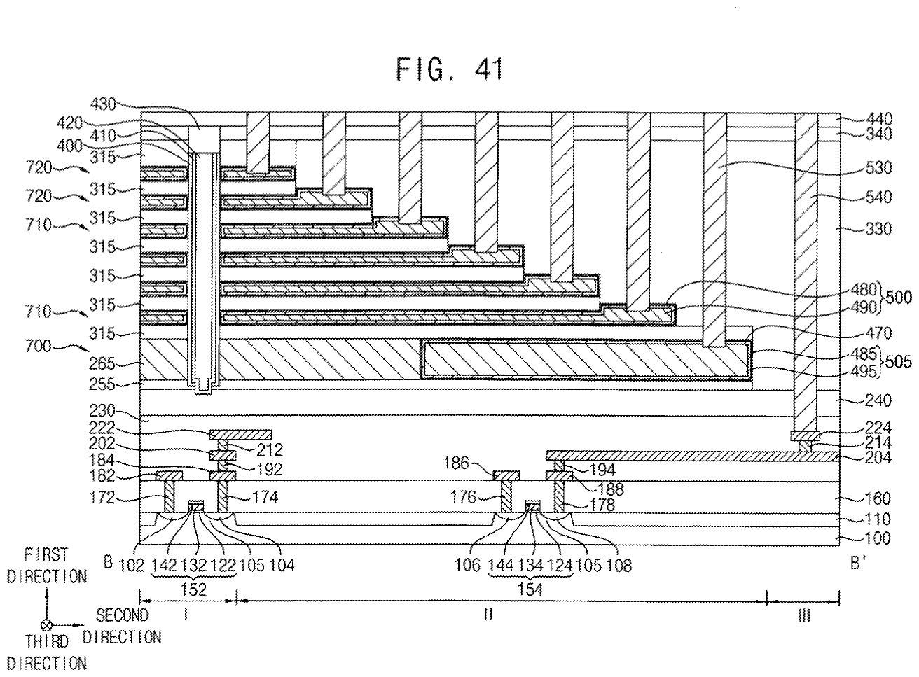

FIGS. 37 to 41 are cross-sectional views illustrating a method of manufacturing a vertical memory device in accordance with exemplary embodiments of the inventive concept. For example, FIGS. 37 to 39 are cross-sectional views taken along lines A-A′ of FIG. 1, and FIGS. 40 and 41 are cross-sectional views taken along lines B-B′ of FIG. 1.

This method of manufacturing the vertical memory device may include processes substantially the same as or similar to the processes described with reference to FIGS. 1 to 21. Accordingly, like reference numerals refer to like elements, and thus, detailed descriptions thereof may be omitted.

Referring to FIG. 37, processes substantially the same as or similar to the processes described with reference to FIGS. 1 to 5 may be performed.

However, the first semiconductor layer 260 and a second sacrificial layer 810 may be formed horizontally on the etch stop layer 250. In an exemplary embodiment of the inventive concept, each of the first semiconductor layer 260 and the second sacrificial layer 810 may extend in the second direction, and a plurality of first semiconductor layers 260 and a plurality of second sacrificial layers 810 may be alternately formed in the third direction. The second sacrificial layer 810 may be overlapped with each of the openings 450 subsequently formed, and, the first semiconductor layer 260 may be overlapped with the first channels 410 between the openings 450. The second sacrificial layer 810 may include a nitride, e,g., silicon nitride.

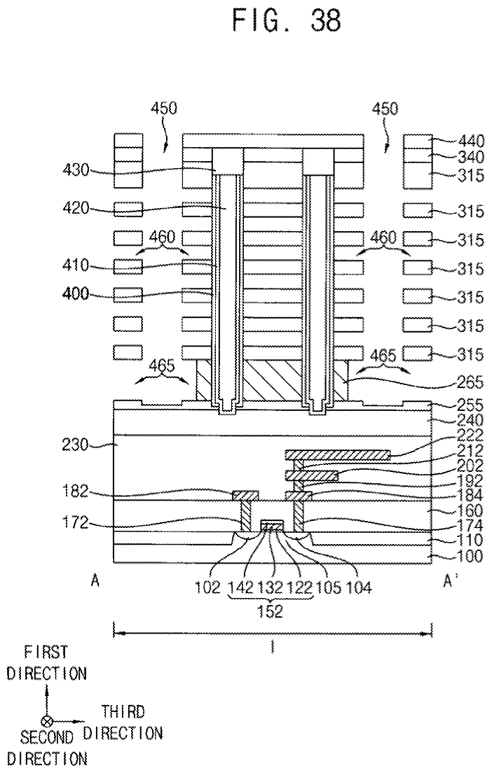

Referring to FIG. 38, processes substantially the same as or similar to the processes described with reference to FIGS. 6 to 17 may be performed.

Accordingly, not only the first sacrificial patterns 325 exposed by the openings 450, but also a second sacrificial pattern of which a sidewall may contact the first semiconductor pattern 265 may also be removed. In this case, first and second gaps 460 and 465 may be formed at regions from which the first sacrificial pattern 325 and the second sacrificial pattern are removed. A sidewall of the first semiconductor pattern 265 may be exposed by the second gap 465.

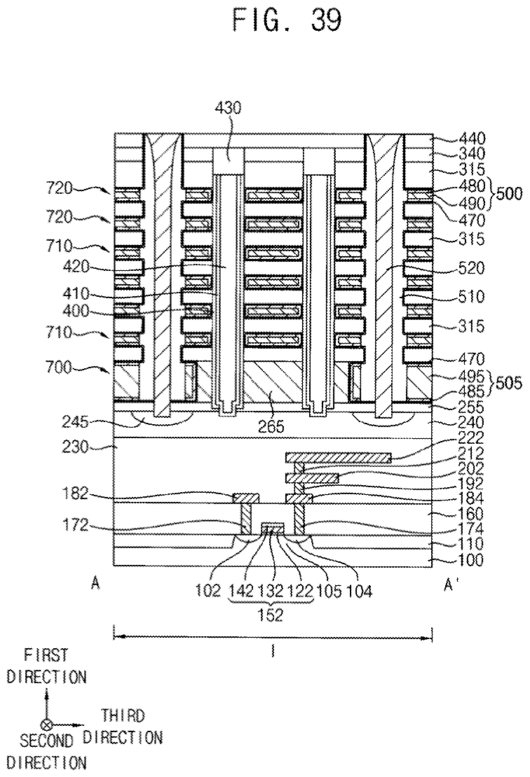

Referring to FIGS. 39 and 40, processes substantially the same as or similar to the processes described with reference to FIGS. 18 to 21 may be performed to complete the fabrication of the vertical memory device.

In the vertical memory device, the GSL 700 may include the first semiconductor pattern 265 through which the first channels 410 may extend. The first semiconductor pattern 265 is extended in the second direction. In addition, the GSL 700 may include the first gate electrode 505 through which the CSL 520 may extend. The first gate electrode 505 is extended in the second direction and is adjacent to the first semiconductor pattern 265 in the third direction. The first gate electrode 505 includes a conductive pattern 495 and a barrier pattern 485. In FIG. 39, the second blocking layer 470 is formed between the first semiconductor pattern 265 and the first gate electrode, however, the inventive concept is not limited. For example, like the embodiments described with reference to FIGS. 30 and 31, the second blocking layer 470 may riot be formed, so that sidewalk of the first semiconductor pattern 265 and the first gate electrode may contact each other.

Referring to FIG. 41, like the embodiment described with reference to FIG. 36, the first gate electrode 505 may be adjacent to not only the first semiconductor pattern 265 in the third direction, but also each of opposite end portions of the first semiconductor pattern 265 in the second direction. In other words, the first semiconductor pattern 265 may extend in the second direction, but may not extend to each of opposite end portions of the mold. In addition, the first semiconductor pattern 265 may be arranged in plural in the third direction. The first gate electrode 505 may including a plurality of first portions that may extend in the second direction and may be spaced apart from each other in the third direction, and a second portion that may be formed on each of the opposite end portions of the mold to connect the first portions with each other and may be adjacent to each of the opposite end portions of the first semiconductor patterns 265.

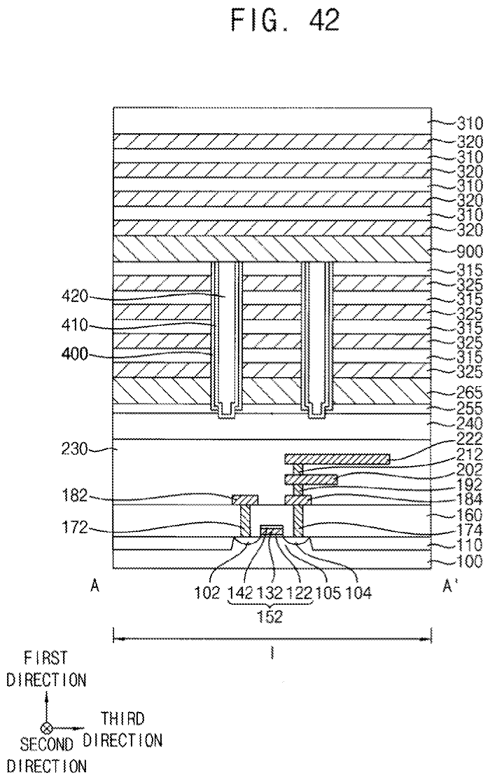

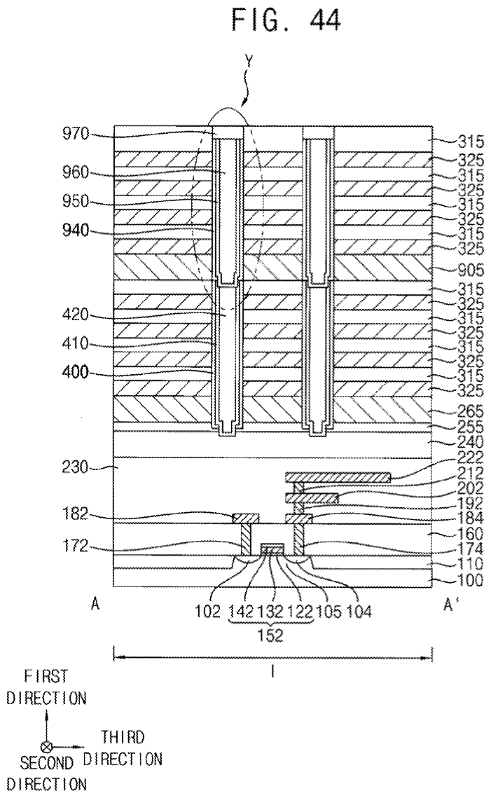

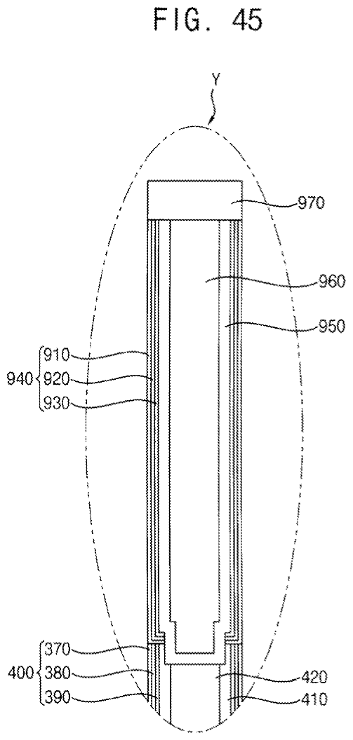

FIGS. 42 to 46 are cross-sectional views illustrating a method of manufacturing a vertical memory device in accordance with exemplary embodiments of the inventive concept. For example, FIGS. 42, 43, 44 and 46 are cross-sectional views taken along lines A-A′ of FIG. 1, and FIG. 45 is an enlarged cross-sectional view of a region Y in FIG. 44.

This method of manufacturing the vertical memory device may include processes substantially the same as or similar to the processes described with reference to FIGS. 1 to 21. Accordingly, like reference numerals refer to like elements, and thus, detailed descriptions thereof may be omitted.

Referring to FIG. 42, processes substantially the same as or similar to the processes described with reference to FIGS. 1 to 15 may be performed.

However, a lower mold including fewer levels of insulation patterns 315 and first sacrificial patterns 325 to be stacked may he formed, and a first structure including the first charge storage structure 400, the first channel 410 and the first filling pattern 420 extending through the lower mold may be formed.

A second semiconductor layer 900 may be formed on the lower mold, and an upper mold layer including the first sacrificial layers 320 and the insulation layers 310 alternately stacked on the second semiconductor layer 900 may be formed.

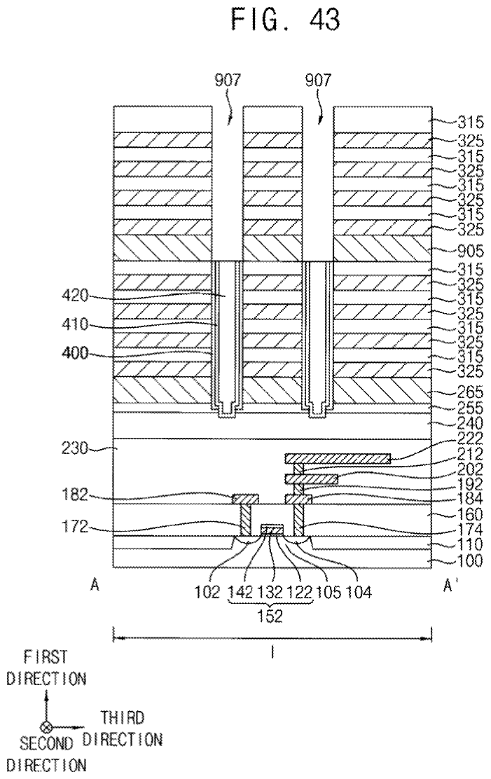

Referring to FIG. 43, processes substantially the same as or similar to the processes described with reference to FIGS. 6 to 12 may be performed.

Accordingly, an upper mold including the first sacrificial patterns 325 and the insulation patterns 315 alternately stacked on a second semiconductor pattern 905 may be formed, and second channel holes 907 may be formed through the upper mold and the second semiconductor pattern 905 to expose upper surfaces of the first structures, respectively, in the lower mold.

Referring to FIGS. 44 and 45, a second structure including a third charge storage structure 940, a second channel 950 and a second filling pattern 960 may be formed in each of the second channel holes 907.

In exemplary embodiments of the inventive concept, the third charge storage structure 940 may contact an upper surface of the first charge storage structure 400 thereunder, the second channel 950 may contact upper surfaces of the first channel 410 and the first filling pattern 420, and the second filling pattern 960 may fill a central portion of the second channel hole 907. The third charge storage structure 940 may include a third blocking pattern 910, a second charge storage pattern 920 and a second tunnel insulation pattern 930 sequentially stacked in the horizontal direction substantially parallel to the upper surface of the substrate 100 from a sidewall of the second channel hole 907.

An upper portion of the second structure may be removed to form a trench, and a second capping pattern 970 may be formed to fill the trench.

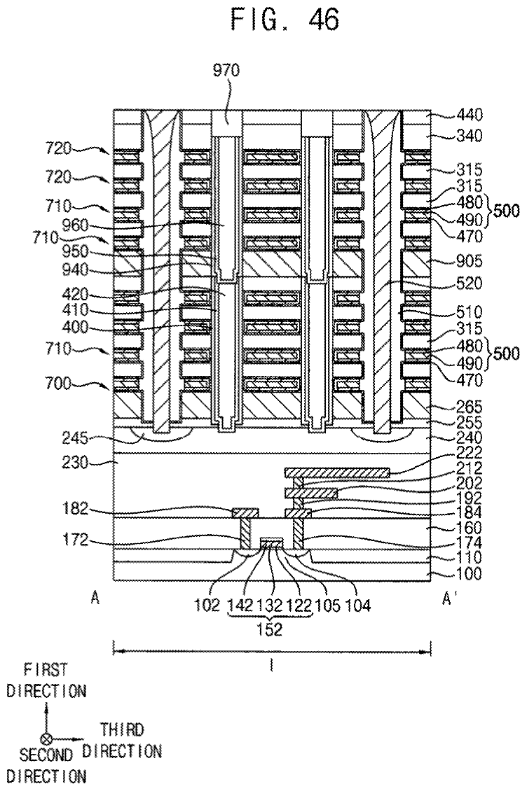

Referring to FIG. 46, processes substantially the same as or similar to the processes described with reference to FIGS. 16 to 21 may be performed to complete the fabrication of the vertical memory device.

Accordingly, a gate electrode structure including the gate electrodes 500 may be formed in the lower and upper molds, and the gate electrode structure may include first, second and third gate electrodes sequentially stacked in the first direction from an upper surface of the base layer 240.

The first semiconductor pattern 265 together with the first gate electrode may form the GSL 700, the second gate electrodes may form the word lines 710, respectively, and the third gate electrode may form the SSL 720. However, some of the word hoes 710 may include the second gate electrode together with the second semiconductor pattern 905 thereunder.

The second blocking layer 470 may cover upper and lower surfaces and a portion of a sidewall of each of the first, second and third gate electrodes, and the CSL 520 may extend through the upper and lower molds to be connected to the fifth impurity region 245 at an upper portion of the base layer 240.

As described above, not only the GSL 700, but also some of the word lines 710 may include the second semiconductor pattern 905 and the gate electrode 500 sequentially stacked.

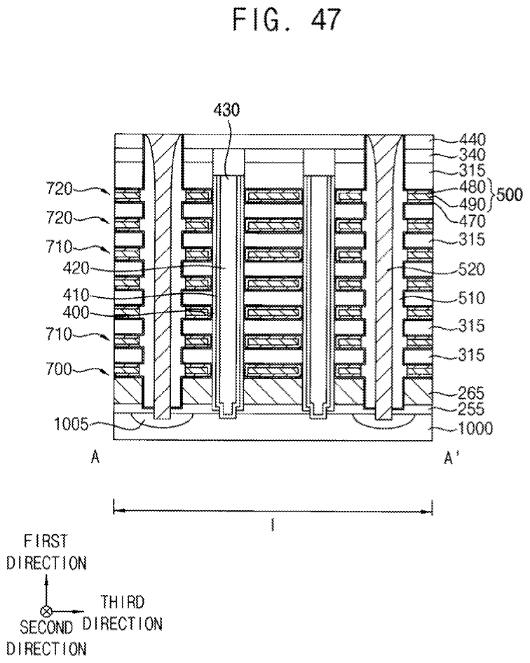

FIG. 47 is a cross-sectional view taken along a line A-A′ of FIG. 1 illustrating a vertical memory device in accordance with exemplary embodiments of the inventive concept.

This vertical memory device may be substantially the same as or similar to the vertical memory device described with reference to FIGS. 19 to 21, except for not having the COP structure. Accordingly, like reference numerals refer to like elements, and thus, detailed descriptions thereof may be omitted.

Referring to FIG. 47, in the vertical memory device, the etch stop pattern 255 may be formed on a substrate 1000, and a gate electrode structure including a plurality of gate electrodes 500 spaced apart from each other in the first direction on the etch stop pattern 255 may be formed.

The gate electrodes 500 may include first, second and third gate electrodes, and the first, second and third gate electrodes may serve as a GSL 700, a word line 710 and an SSL 720, respectively.

In exemplary embodiments of the inventive concept, the GSL 700 may include the first gate electrode, and may further include the first semiconductor pattern 265 thereunder. In addition, some of the word lines 710 may include the second gate electrode and the second semiconductor pattern 905 thereunder.

The vertical memory device may have a structure in which a circuit pattern may be formed in a peripheral circuit region surrounding a memory cell array. Accordingly, the etch stop pattern 225 may be formed on the substrate 1000 including single crystalline silicon, and the first channels 410 extending through the mold on the etch stop pattern 225 may have a constant length in the first direction, so that a current applied to the first channels 410 may have a constant value. The GSL 700 may include not only the first semiconductor pattern 265, but also the first gate electrode including a metal, and may have a relatively low resistance.

While the inventive concept has been described with reference to exemplary embodiments thereof, those skilled in the art will readily appreciate that many modifications are possible without departing from the scope of the inventive concept as defined by the following claims.

What is claimed is:

1. A vertical memory device, comprising:
a gate electrode structure including a ground selection line (GSL), a word line and a string selection line (SSL) sequentially stacked on a substrate in a first direction substantially perpendicular to an upper surface of the substrate; and
a channel extending through the gate electrode structure in the first direction,
wherein the GSL has a doped polysilicon pattern and a first metal pattern including a metal or a metal silicide, and the doped polysilicon pattern and the first metal pattern are stacked in the first direction, and
wherein each of the word line and the SSL has a second metal pattern including a metal.

2. The vertical memory device of claim 1, wherein the doped polysilicon pattern and the first metal pattern are sequentially stacked in the first direction from the upper surface of the substrate, and
wherein the first metal pattern and the second metal pattern include substantially the same metal.

3. The vertical memory device of claim 2, wherein the GSL further includes a first barrier pattern covering upper and lower surfaces and a sidewall of the first metal pattern facing an outer sidewall of the channel, and including a metal nitride, and
each of the word line and the SSL further includes a second barrier pattern covering upper and lower surfaces and a sidewall of the second metal pattern facing the outer sidewall of the channel, and including a metal nitride.

4. The vertical memory device of claim 3, further comprising:
a blocking layer covering upper and lower surfaces and a sidewall of each of the first and second barrier patterns facing the outer sidewall of the channel, and including a metal oxide,
wherein the blocking layer contacts an upper surface of the doped polysilicon pattern.

5. The vertical memory device of claim 3, wherein the first barrier pattern contacts an upper surface of the doped polysilicon pattern.

6. The vertical memory device of claim 5, further comprising:
a charge storage structure covering the outer sidewall of the channel and including a tunnel insulation pattern, a charge storage pattern, a first blocking pattern and a second blocking pattern sequentially stacked in a second direction substantially parallel to the upper surface of the substrate.

7. The vertical memory device of claim 6, wherein each of the tunnel insulation pattern and the first blocking pattern includes silicon oxide, the charge storage pattern includes silicon nitride, and the second blocking pattern includes a metal oxide.

8. The vertical memory device of claim 1, wherein the doped polysilicon pattern and the first metal pattern contact each other in the first direction, and
wherein the first metal pattern includes a metal silicide.

9. The vertical memory device of claim 8, wherein the first metal pattern further includes a tungsten silicide pattern and a tungsten pattern sequentially stacked in the first direction from an upper surface of the doped polysilicon pattern.

10. The vertical memory device of claim 1, wherein the first metal pattern and the doped polysilicon pattern are sequentially stacked in the first direction to contact each other, and
wherein the first metal pattern includes a metal silicide.

11. The vertical memory device of claim 1, further comprising:
a circuit pattern on the substrate; and
a base layer on the circuit pattern, the base layer contacting a lower surface of the channel, and including polysilicon.

12. The vertical memory device of claim 1, wherein the substrate includes single crystalline silicon, and contacts a lower surface of the channel.

13. A vertical memory device, comprising:
a gate electrode structure including a ground selection line (GSL), a word line and a string selection line (SSL) sequentially stacked on a substrate in a first direction substantially perpendicular to an upper surface of the substrate; and
a channel extending through the gate electrode structure in the first direction,
wherein the GSL has a doped polysilicon pattern and a first metal pattern including a metal or a metal silicide, and the doped polysilicon pattern and the first metal pattern are arranged in a second direction substantially parallel to the upper surface of the substrate, and
wherein each of the word line and the SSL has a second metal pattern including a metal.

14. The vertical memory device of claim 13, wherein a sidewall of the doped polysilicon pattern and a sidewall of the first metal pattern contact each other.

15. The vertical memory device of claim 14, wherein the GSL extends in the second direction, the doped polysilicon pattern is formed at a central portion of the GSL in the second direction, and the first metal pattern is formed at an edge portion of the GSL in the second direction.

16. The vertical memory device of claim 13, wherein the GSL further includes a first barrier pattern covering upper and lower surfaces and a sidewall of the first metal pattern facing a sidewall of the doped polysilicon pattern, and including a metal nitride, and
wherein each of the word line and the SSL further includes a second barrier pattern covering upper and lower surfaces and a sidewall of the second metal pattern facing an outer sidewall of the channel, and including a metal nitride.

17. The vertical memory device of claim 16, further comprising:
a blocking layer covering upper and lower surfaces and a sidewall of the first barrier pattern facing the sidewall of the doped polysilicon pattern, and covering upper and lower surfaces and a sidewall of the second barrier pattern facing the outer sidewall of the channel,
wherein the blocking layer contacts the sidewall of the doped polysilicon pattern.

18. A vertical memory device, comprising:
a gate electrode structure including a plurality of gate electrodes sequentially stacked in a vertical direction with respect to an upper surface of a substrate; and
a channel structure extending through the gate electrode structure in the vertical direction,
wherein a first gate electrode of the plurality of gate electrodes has a doped polysilicon pattern and a first metal pattern, and
wherein each of second gate electrodes of the plurality of gate electrodes has a second metal pattern.

19. The vertical memory device of claim 18, wherein the first gate electrode is a closest one of the plurality of gate electrodes to the upper surface of the substrate.

20. The vertical memory device of claim 18, wherein the first gate electrode is arranged between an uppermost gate electrode and a lowermost gate electrode with respect to the upper surface of the substrate,
wherein the channel structure includes first and second channels sequentially stacked in the vertical direction, and
wherein a lower surface of the second channel contacts an upper surface of the first channel.
